(19) United States
(12) Patent Application Publication
(10) Pub. No.: US 2023/0187581 A1
(43) Pub. Date: Jun. 15, 2023

(54) DISPLAY DEVICE

(71) Applicant: Samsung Display Co., LTD., Yongin-si (KR)

(72) Inventors: So Young YEO, Suwon-si (KR); Ok Yi LEE, Seoul (KR); Soo Chul KIM, Hwaseong-si (KR); Jin Taek PARK, Seoul (KR); Dae Ho SONG, Hwaseong-si (KR); Ki Beom LEE, Seoul (KR)

(21) Appl. No.: 17/883,181

(22) Filed: Aug. 8, 2022

(30) Foreign Application Priority Data
Dec. 9, 2021 (KR) 10-2021-0175513

(51) Int. Cl. H01L 33/38; H01L 27/15

(52) U.S. Cl. CPC H01L 33/382; H01L 27/156

(57) ABSTRACT

A display device is provided. The display device comprises a substrate, contact electrodes and a common contact electrode on the substrate, light-emitting elements on the contact electrodes, and a common connecting electrode on the common contact electrode and connected to the light-emitting elements, wherein the common connecting electrode includes first conductive patterns, which are in contact with the common contact electrode.

### CROSS-REFERENCE TO RELATED APPLICATION

This application claims priority to, and the benefit of, Korean Patent Application No. 10-2021-0175513 filed on Dec. 9, 2021 in the Korean Intellectual Property Office, the contents of which in its entirety are herein incorporated by reference.

### BACKGROUND

### 1. Field

The present disclosure relates to a display device.

### 2. Description of the Related Art

As the information society has developed, the demand for display devices for displaying images has diversified. Here, the display devices may be flat panel display devices, such as a liquid crystal display (LCD) device, a field emission display (FED) device, or a light-emitting display device, and the light-emitting display device may be one of an organic light-emitting display device including organic light-emitting diodes (OLEDs) as light-emitting elements, an inorganic light-emitting display device including inorganic semiconductor elements as light-emitting elements, and a microscopic light-emitting diode (microLED) display device including microLEDs as light-emitting elements.

Meanwhile, head-mounted displays (HMDs) equipped with light-emitting display devices have been developed. HMDs are devices that can be worn like glasses or a helmet and forms a focus at a close distance from the eyes of a user for providing virtual reality (VR) or augmented reality (AR).

A high-resolution microLED display panel including microLEDs can be applied to an HMD. As the microLEDs emit light of a single light, the microLEDs may include wavelength conversion layers for converting the wavelength of light emitted from the microLEDs.

### SUMMARY

Aspects of the present disclosure provide a display device capable of reducing or preventing any misalignment, and addressing the problem of electrodes melting and spilling over to a display area, during the bonding of a semiconductor circuit substrate and a light-emitting element layer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the disclosure, a display device includes a substrate, contact electrodes and a common contact electrode on the substrate, light-emitting elements respectively on the contact electrodes, and a common connecting electrode on the common contact electrode, connected to the light-emitting elements, and including first conductive patterns in contact with the common contact electrode.

The first conductive patterns may be spaced apart from one another, and may be formed as dots or lines.

The light-emitting elements may include a first semiconductor layer, an active layer on the first semiconductor layer, a second semiconductor layer on the active layer, and a third semiconductor layer on the second semiconductor layer, wherein the second semiconductor layer is a common layer connected in common to the light-emitting elements.

The first conductive patterns may be between, and in contact with, the second semiconductor layer and the common contact electrode.

The first conductive patterns may include a same material as the contact electrodes.

The first conductive patterns may account for about 10% to about 50% of a total area of the common contact electrode.

The common contact electrode may further include second conductive patterns spaced apart from one another, and respectively overlap the first conductive patterns.

The second conductive patterns may correspond one-to-one to the first conductive patterns.

The display device may further include a common electrode between the substrate and the common contact electrode, wherein the second conductive patterns account for about 10% to about 50% of a total area of the common electrode.

The light-emitting elements may be in a display area, wherein the common contact electrode and the common connecting electrode are in a non-display area surrounding the display area.

According to one or more embodiments of the disclosure, a display device includes a substrate, contact electrodes and a common contact electrode on the substrate, light-emitting elements on the contact electrodes, and a common connecting electrode on the common contact electrode, and connected to the light-emitting elements, wherein the common contact electrode includes conductive patterns, which are in contact with the common connecting electrode.

The conductive patterns may account for 10% to 50% of a total area of the common connecting electrode.

According to one or more embodiments of the disclosure, a display device includes a substrate including a display area and a non-display area, light-emitting elements in the display area, and dummy patterns in the non-display area, adjacent to at least one side of the substrate, and having respective lengths that gradually increase away from a center of a first side of the substrate.

The first side of the substrate may be a long side of the substrate, wherein the lengths of the dummy patterns extend along the long side.

The dummy patterns may be further located along a second side extending in a direction crossing a direction of the first side of the substrate, the second side being a short side of the substrate.

The light-emitting elements may include a first semiconductor layer, an active layer on the first semiconductor layer, a second semiconductor layer on the active layer, and a third semiconductor layer on the second semiconductor layer, wherein the display device further includes connecting electrodes connected to the first semiconductor layer.

The dummy patterns may include a same material as the connecting electrodes.

According to one or more embodiments of the disclosure, a display device includes a substrate including a display area and a non-display area, and light-emitting elements in the display area, wherein the substrate defines holes in the non-display area, adjacent to at least one side of the substrate, and having respective lengths gradually increasing away from a center of the at least one side of the substrate.

The holes may penetrate the substrate.

The holes may be formed in the substrate.

According to the aforementioned and other embodiments of the present disclosure, as the area of contact of a common connecting electrode and a common contact electrode can be reduced during the bonding of a semiconductor circuit substrate and a light-emitting element layer, the amounts of materials melted and flowing into a display area can be reduced so that the likelihood of short circuits with light-emitting elements can be reduced or prevented.

Also, as a plurality of dummy patterns or holes are formed in a second substrate of the light-emitting element layer, heat from the light-emitting element layer can be released during the bonding of the semiconductor circuit substrate and the light-emitting element layer, and as a result, the alignment of the semiconductor circuit substrate and the light-emitting element layer can be improved.

It should be noted that the aspects of the present disclosure are not limited to those described above, and other aspects of the present disclosure will be apparent from the following description.

### BRIEF DESCRIPTION OF THE DRAWINGS

The above and other aspects of the present disclosure will become more apparent by describing in detail embodiments thereof with reference to the attached drawings, in which:

FIG. 1 is a layout view of a display device, according to one or more embodiments of the present disclosure;

FIG. 2 is a layout view of the area A of FIG. 1;

FIG. 3 is a layout view illustrating a plurality of pixels of the display device of FIG. 1;

FIG. 4 is a cross-sectional view, taken along the line A-A′ of FIG. 2, of a display panel of the display device of FIG. 1;

FIG. 5 is an equivalent circuit diagram of a pixel of the display device of FIG. 1, according to one or more embodiments;

FIG. 6 is an equivalent circuit diagram of a pixel of the display device of FIG. 1, according to one or more other embodiments;

FIG. 7 is an equivalent circuit diagram of a pixel of the display device of FIG. 1, according to one or more other embodiments;

FIG. 8 is a cross-sectional view, taken along the line B-B′ of FIG. 2, of the display panel of FIG. 4;

FIG. 9 is a plan view of a light-emitting element layer of the display panel of FIG. 4;

FIG. 10 is a cross-sectional view of a light-emitting element of the display panel of FIG. 4;

FIG. 11 is a cross-sectional view, taken along the line C-C′ of FIG. 1, of the display panel of FIG. 4, according to one or more embodiments;

FIG. 12A is an enlarged layout view of the area B of FIG. 1, according to one or more embodiments;

FIG. 12B is an enlarged layout view of the area B of FIG. 1, according to one or more other embodiments;

FIG. 12C is an enlarged layout view of the area B of FIG. 1, according to one or more other embodiments;

FIG. 13A is an enlarged layout view of the area B of FIG. 1, according to one or more other embodiments;

FIG. 13B is an enlarged layout view of the area B of FIG. 1, according to one or more other embodiments;

FIG. 13C is an enlarged layout view of the area B of FIG. 1, according to one or more other embodiments;

FIG. 14A is an enlarged layout view of the area B of FIG. 1, according to one or more other embodiments;

FIG. 14B is an enlarged layout view of the area B of FIG. 1, according to one or more other embodiments;

FIG. 14C is an enlarged layout view of the area B of FIG. 1, according to one or more other embodiments;

FIG. 15 is a cross-sectional view, taken along the line C-C of FIG. 1, of a display panel of the display device of FIG. 1, according to one or more other embodiments;

FIG. 16 is a cross-sectional view, taken along the line C-C of FIG. 1, of a display panel of the display device of FIG. 1, according to one or more other embodiments;

FIG. 17 is a plan view of the display panel of FIG. 4, according to one or more embodiments;

FIG. 18 is a cross-sectional view taken along the line D-D′ of FIG. 17;

FIG. 19 is a plan view of a display panel of the display device of FIG. 1, according to one or more other embodiments;

FIG. 20 is a plan view of a display panel of the display device of FIG. 1, according to one or more other embodiments;

FIG. 21 is a cross-sectional view of a display panel of the display device of FIG. 1, according to one or more other embodiments;

FIG. 22 is a cross-sectional view of a display panel of the display device of FIG. 1, according to one or more other embodiments;

FIGS. 23 through 27 are layout views illustrating the area A of FIG. 1, according to one or more other embodiments;

FIG. 28 is a cross-sectional view taken along the line E-E′ of FIG. 23.

FIG. 29 is a flowchart illustrating a method of fabricating a display panel, according to one or more embodiments of the present disclosure;

FIGS. 30 through 37 are cross-sectional views illustrating the method of fabricating a display panel, according to one or more embodiments of the present disclosure;

FIG. 38 is a perspective view of a virtual reality (VR) device including a display device, according to one or more embodiments of the present disclosure;

FIG. 39 is a perspective view of a smart device including a display device, according to one or more embodiments of the present disclosure;

FIG. 40 is a perspective view of an automobile including a display device, according to one or more embodiments of the present disclosure; and

FIG. 41 is a perspective view of a transparent display device including a display device, according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

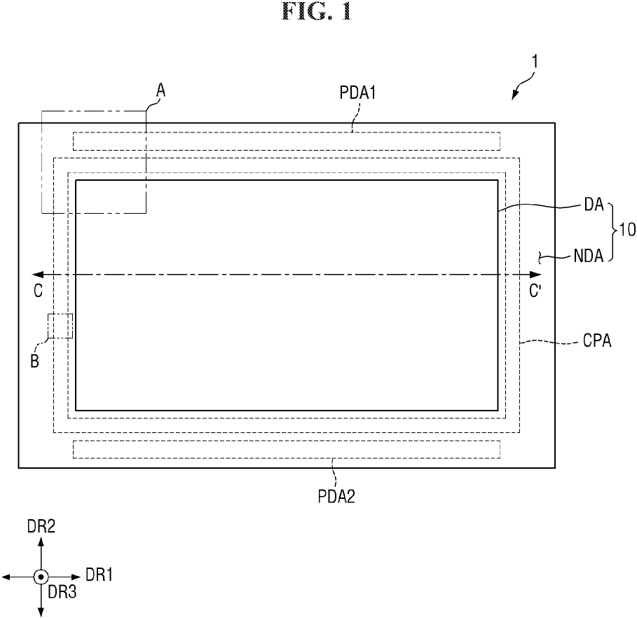

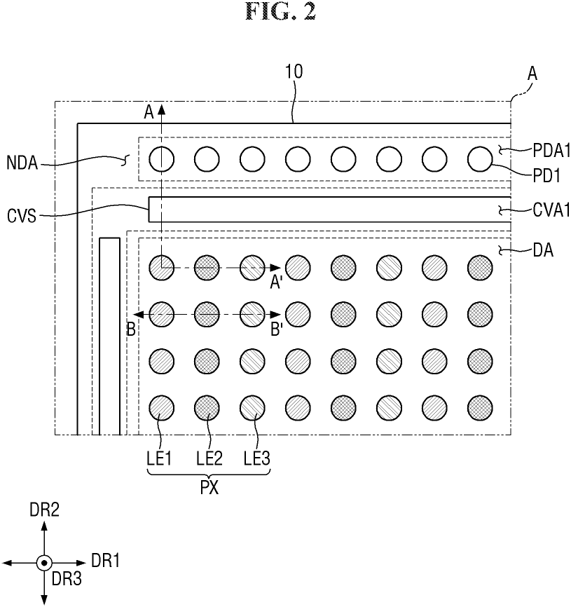

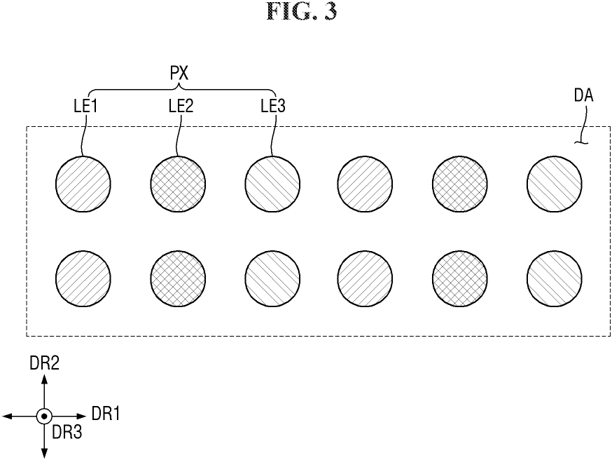

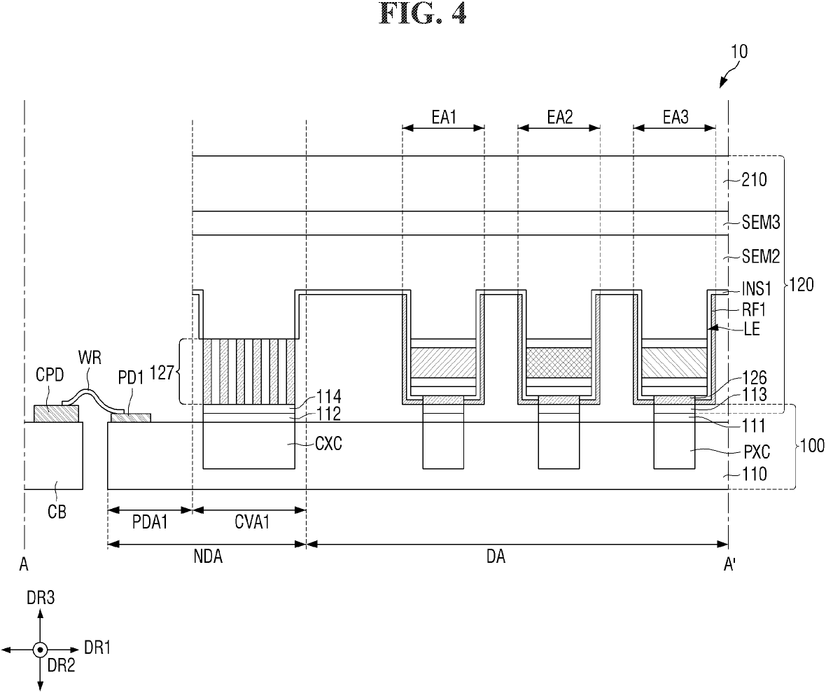

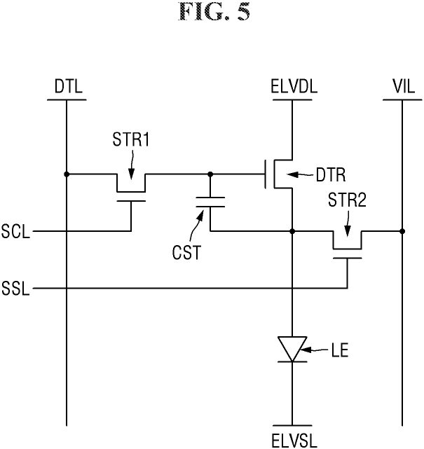

FIG. 1 is a layout view of a display device, according to one or more embodiments of the present disclosure. FIG. 2 is a layout view of the area A of FIG. 1. FIG. 3 is a layout view illustrating a plurality of pixels of the display device of FIG. 1.

FIGS. 1 through 3 illustrate a display device 1 according to one or more embodiments of the present disclosure as a micro-light-emitting diode (microLED) display device including microLEDs as light-emitting elements, but the present disclosure is not limited thereto.

Also, FIGS. 1 through 3 illustrate the display device 1 as having a light-emitting diode-on-silicon (LEDoS) configuration where LEDs are located on a semiconductor circuit substrate obtained by a semiconductor process, but the present disclosure is not limited thereto.

Referring to FIGS. 1 through 3, a first direction DR1 may refer to the horizontal direction of a display panel 10, a second direction DR2 may refer to the vertical direction of the display panel 10, and a third direction DR3 may refer to the thickness direction of the display panel 10 or a semiconductor circuit substrate 100 (e.g., see FIG. 4). In this case, the terms “left,” “right,” “upper,” and “lower” may refer to their respective directions as viewed from above the display panel 10. For example, the term “right” may refer to a first side in the first direction DR1, the term “left” may refer to a second side in the first direction DR1, the term “upper” may refer to a first side in the second direction DR2, and the term “lower” may refer to a second side in the second direction DR2. Also, the terms “upper” and “lower” may refer to a first side in the third direction DR3 and a second side in the third direction DR3, respectively.

The display device 1 includes the display panel 10, which includes a display area DA and a non-display area NDA.

In a plan view, the display panel 10 may have a rectangular shape having long sides in the first direction DR1 and short sides in the second direction DR2, but the planar shape of the display panel 10 is not particularly limited. That is, the display panel 10 may have various other shapes, such as a non-tetragonal polygonal shape, a circular shape, an elliptical shape, or an atypical shape in a plan view.

The display area DA may be an area where an image is displayed, and the non-display area NDA may be an area where an image is not displayed. The planar shape of the display area DA may conform to the planar shape of the display panel 10. FIG. 1 illustrates that the display area DA has a rectangular shape in a plan view. The display area DA may be located in the middle of the display panel 10. The non-display area NDA may be located around the display area DA in plan view. The non-display area NDA may surround the display area DA in plan view.

The display area DA of the display panel 10 may include a plurality of pixels PX. The pixels may be defined as minimal emission units capable of displaying white light.

Each of the pixels PX may include first through third light-emitting elements LE1, LE2, and LE3, which emit light. Each of the pixels PX is illustrated as including three light-emitting elements, but the present disclosure is not limited thereto. Also, each of the first through third light-emitting elements LE1 through LE3 is illustrated as having a circular shape in a plan view, but the present disclosure is not limited thereto.

First light-emitting elements LE1 may emit first light. The first light may be blue-wavelength light. For example, the first light may have a main peak wavelength of about 370 nm to about 460 nm, but the present disclosure is not limited thereto.

Second light-emitting elements LE2 may emit second light. The second light may be green-wavelength light. For example, the second light may have a main peak wavelength of about 480 nm to about 560 nm, but the present disclosure is not limited thereto.

Third light-emitting elements LE3 may emit the first light. The first light may be blue-wavelength light. For example, the first light may have a main peak wavelength of about 370 nm to about 460 nm, but the present disclosure is not limited thereto. The third light-emitting elements LE3 may emit the first light, and the first light emitted by the third light-emitting elements LE3 may be converted into third light by a wavelength conversion layer and/or color filters that will be described later. The third light may be red-wavelength light having a wavelength of about 600 nm to about 750 nm.

The first light-emitting elements LE1, the second light-emitting elements LE2, and the third light-emitting elements LE3 may be alternately arranged in the first direction DR1. For example, the first light-emitting elements LE1, the second light-emitting elements LE2, and the third light-emitting elements LE3 may be arranged in the order of first, second, and third light-emitting elements LE1, LE2, and LE3 along the first direction DR1. The first light-emitting elements LE1 may be arranged in the second direction DR2. The second light-emitting elements LE2 may be arranged in the second direction DR2. The third light-emitting elements LE3 may be arranged in the second direction DR2.

The non-display area NDA may include a first common voltage supply area CVA1, a first pad unit PDA1, and a second pad unit PDA2.

The first common voltage supply area CVA1 may be located between the first pad unit PDA1 and the display area DA. The first common voltage supply area CVA1 also may be located between the second pad unit PDA2 and the display area DA. The first common voltage supply area CVA1 may include a plurality of common voltage supply units CVS. A common voltage may be supplied to light-emitting elements (LE1, LE2, and LE3) through the common voltage supply units CVS.

The common voltage supply units CVS of the first common voltage supply area CVA1 may be electrically connected to one of first pads PD1 of the first pad unit PDA1 and the second pad unit PDA2. That is, the common voltage supply units CVS of the first common voltage supply area CVA1 may receive the common voltage from one of the first pads of the first pad unit PDA1 and the second pad unit PDA2.

FIG. 1 illustrates that a common electrode connection unit CPA completely surrounds the display area DA, but the present disclosure is not limited thereto. Alternatively, the common electrode connection unit CPA may be located on one side, both sides, or at least three sides of the display area DA.

The first pad unit PDA1 may be located in an upper part of the display panel 10. The first pad unit PDA1 may include the first pads PD1, which are connected to an external circuit board.

The second pad unit PDA2 may be located in a lower part of the display panel 10. The second pad unit PDA2 may include the second pads PD2, which are to be connected to the external circuit board. The second pad unit PDA2 may be omitted in one or more embodiments.

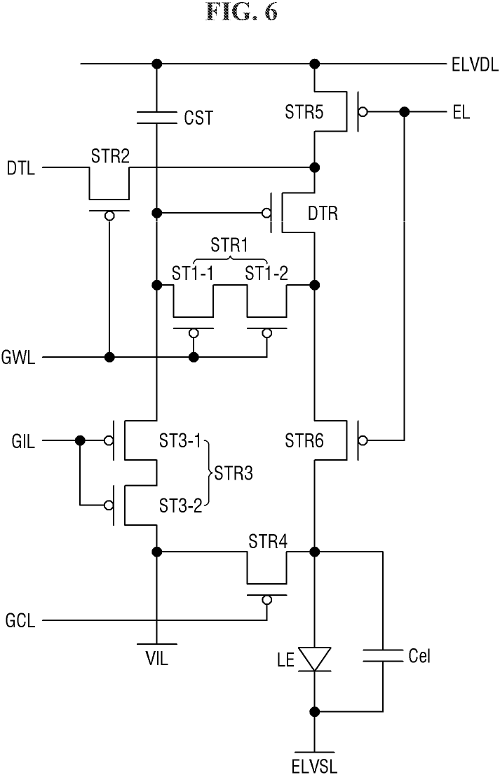

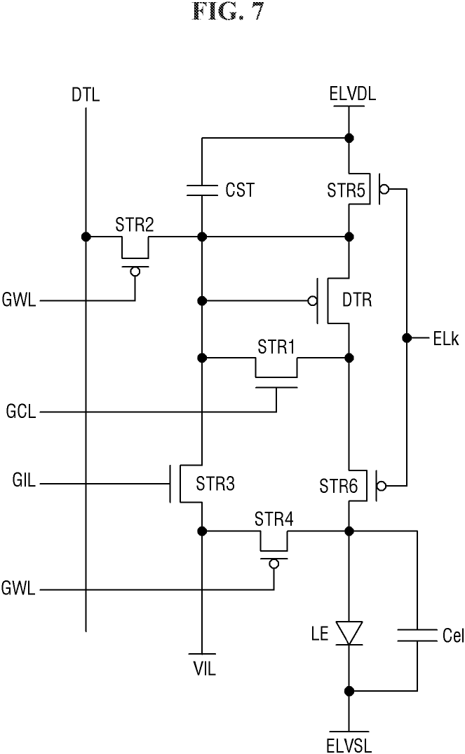

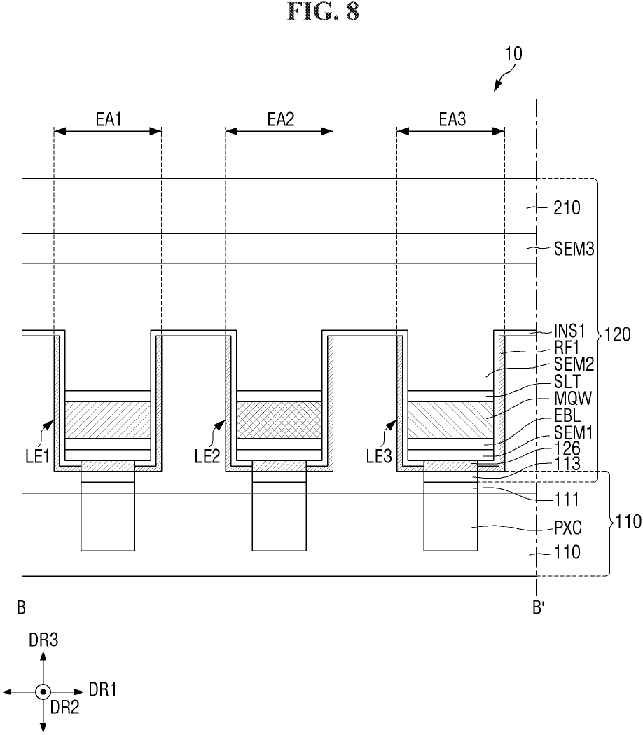

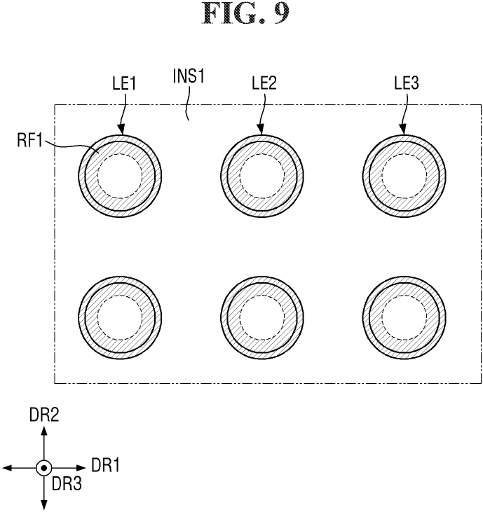

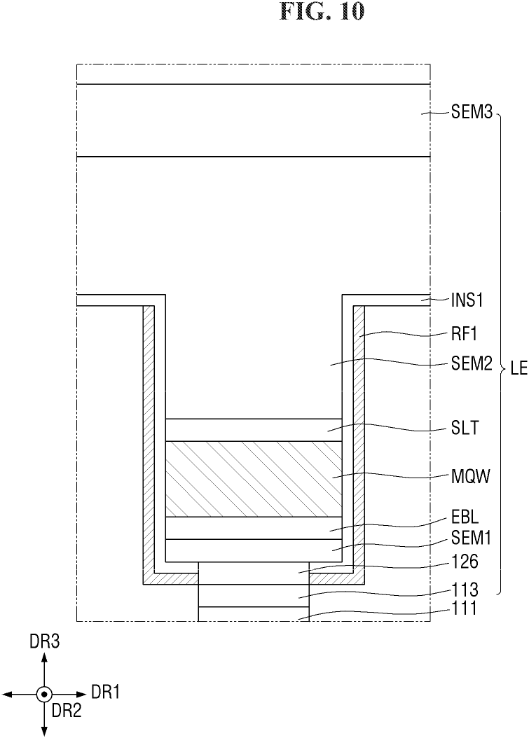

FIG. 4 is a cross-sectional view, taken along the line A-A′ of FIG. 2, of a display panel of the display device of FIG. 1. FIG. 5 is an equivalent circuit diagram of a pixel of the display device of FIG. 1, according to one or more embodiments. FIG. 6 is an equivalent circuit diagram of a pixel of the display device of FIG. 1, according to one or more other embodiments. FIG. 7 is an equivalent circuit diagram of a pixel of the display device of FIG. 1, according to one or more other embodiments. FIG. 8 is a cross-sectional view, taken along the line B-B′ of FIG. 2, of the display panel of FIG. 4. FIG. 9 is a plan view of a light-emitting element layer of the display panel of FIG. 4. FIG. 10 is a cross-sectional view of a light-emitting element of the display panel of FIG. 4.

Referring to FIGS. 4 through 10, a display panel 10 may include a semiconductor circuit substrate 100 and a light-emitting element layer 120.

The semiconductor circuit substrate 100 may include a first substrate 110, a plurality of pixel circuit units PXC, a common circuit unit CXC, pixel electrodes 111, a common electrode 112, first pads PD1, contact electrodes 113, and a common contact electrode 114.

The first substrate 110 may be a silicon wafer substrate formed by a semiconductor process. The pixel circuit units PXC and the common circuit unit CXC of the first substrate 110 may be formed by a semiconductor process(es).

The pixel circuit units PXC may be located in a display area DA. The pixel circuit units PXC may be connected to their respective pixel electrodes 111. For example, the pixel circuit units PXC may be connected one-to-one to their respective pixel electrodes 111. The pixel circuit units PXC may overlap with light-emitting elements LE in the third direction DR3.

Each of the pixel circuit units PXC may include at least one transistor formed by a semiconductor process. Each of the pixel circuit units PXC may include at least one capacitor formed by a semiconductor process. The pixel circuit units PXC may include, for example, complementary metal-oxide semiconductor (CMOS) circuits. The pixel circuit units PXC may apply a pixel voltage or an anode voltage to the pixel electrodes 111.

Referring to FIG. 5, a pixel circuit unit PXC may include three transistors (e.g., a driving transistor DTR, a first transistor STR1, and a second transistor STR2), and a capacitor CST for a storage.

A light-emitting element LE emits light in accordance with a current supplied thereto through the driving transistor DTR. The light-emitting element LE may be implemented as an inorganic light-emitting diode (LED), an organic LED, a microLED, or a nanoLED.

A first electrode (or an anode) of the light-emitting element LE may be connected to the source electrode of the driving transistor DTR, a second electrode (or a cathode) of the light-emitting element LE may be connected to a second power supply line ELVSL, to which a low-potential voltage (or a second power supply voltage), which is lower than a high-potential voltage (or a first power supply voltage) from a first power supply line ELVDL, is supplied.

The driving transistor DTR may control a current flowing from a first power supply line ELVDL, to which the first power supply voltage is supplied, to the light-emitting element LE in accordance with the difference in voltage between the gate electrode and the source electrode of the driving transistor DTR. The gate electrode of the driving transistor DTR may be connected to the first electrode of the first transistor STR1, the source electrode of the driving transistor DTR may be connected to the anode of the light-emitting element LE, and the drain electrode of the driving transistor DTR may be connected to the first power supply line ELVDL.

The first transistor STR1 may be turned on by a scan signal from a scan line SCL to connect the data line to the gate electrode of the driving transistor DTR. The gate electrode of the first transistor STR1 may be connected to the scan line SCL, the first electrode of the first transistor STR1 may be connected to the gate electrode of the driving transistor DTR, and the second electrode of the first transistor STR1 may be connected to a data line DTL.

The second transistor STR2 may be turned on by a sensing signal from a sensing signal line SSL to connect an initialization voltage line VIL to the source electrode of the driving transistor DTR. The gate electrode of the second transistor STR2 may be connected to the sensing signal line SSL, the first electrode of the second transistor STR2 may be connected to the initialization voltage line VIL, and the second electrode of the second transistor STR2 may be connected to the source electrode of the driving transistor DTR.

The first electrodes of the first and second transistors STR1 and STR2 may be, but are not limited to, source electrodes, and the second electrodes of the first and second transistors STR1 and STR2 may be, but are not limited to, drain electrodes.

The capacitor CST is formed between the gate electrode and the source electrode of the driving transistor DTR. The capacitor CST stores a differential voltage between the voltage at the gate electrode of the driving transistor DTR and the voltage at the source electrode of the driving transistor DTR.

The driving transistor DTR and the first and second transistors STR1 and STR2 may be formed as thin-film transistors (TFTs). FIG. 5 illustrates that the driving transistor DTR and the first and second transistors STR1 and STR2 are N-type metal-oxide semiconductor field-effect transistors (MOSFETs), but the present disclosure is not limited thereto. Alternatively, the driving transistor DTR and the first and second transistors STR1 and STR2 may be P-type MOSFETs. Yet alternatively, some of the driving transistor DTR and the first and second transistors STR1 and STR2 may be formed as N-type MOSFETs, and some of the driving transistor DTR and the first and second transistors STR1 and STR may be formed as P-type MOSFETs.

Referring to FIG. 6, a first electrode of a light-emitting element LE of a pixel circuit unit PXC may be connected to a first electrode of a fourth transistor STR4 and a second electrode of a sixth transistor STR6, and a second electrode of the light-emitting element LE may be connected to a second power supply line ELVSL. A parasitic capacitor Cel may be formed between the first and second electrodes of the light-emitting element LE.

The pixel circuit unit PXC may include a driving transistor DTR, switching elements, and a capacitor CST. The switching elements may include first through sixth transistors STR1 through STR6.

The driving transistor DTR includes a gate electrode, a first electrode, and a second electrode. The driving transistor DTR controls a drain-source current (or a driving current) that flows between the first and second electrodes of the driving transistor DTR in accordance with a data voltage applied to the gate electrode of the driving transistor DTR.

The capacitor CST is formed between the gate electrode of the driving transistor DTR and a first power supply line ELVDL. A first electrode of the capacitor CST may be connected to the gate electrode of the driving transistor DTR, and a second electrode of the capacitor CST may be connected to the first power supply line ELVDL.

The first electrodes of the driving transistor DTR and the first through sixth transistors STR1 through STR6 may be source electrodes, and the second electrodes of the driving transistor DTR and the first through sixth transistors STR1 through STR6 may be drain electrodes. Alternatively, the first electrodes of the driving transistor DTR and the first through sixth transistors STR1 through STR6 may be drain electrodes, and the second electrodes of the first electrodes of the driving transistor DTR and the first through sixth transistors STR1 through STR6 may be source electrodes.

Active layers of the first through sixth transistors STR1 through STR6 and the driving transistor DTR may be formed of one of polysilicon, amorphous silicon, and an oxide semiconductor. Active layers of the first through sixth transistors STR1 through STR6 and the driving transistor DTR may be formed of polysilicon by a low-temperature polysilicon (LTPS) process.

FIG. 6 illustrates that the first through sixth transistors STR1 through STR6 and the driving transistor DTR are formed as P-type MOSFETs, but the present disclosure is not limited thereto. Alternatively, the first through sixth transistors STR1 through STR6 and the driving transistor DTR may be formed as N-type MOSFETs.

A first power supply voltage from the first power supply line ELVDL, a second power supply voltage from the second power supply line ELVSL, and a third power supply voltage from a third power supply line VIL may be set in consideration of the characteristics of the driving transistor DTR and the characteristics of a light-emitting element LE.

Referring to FIG. 7, a pixel circuit unit PXC differs from its counterpart of FIG. 6 in that a driving transistor DTR and second, fourth, fifth, and sixth transistors STR2, STR4, STR5, and STR6 are formed as P-type MOSFETs, and first and third transistors STR1 and STR3 are formed as N-type MOSFETs.

Active layers of the driving transistor DTR and the second, fourth, fifth, and sixth transistors STR2, STR4, STR5, and STR6, which are formed as P-type MOSFETs, may be formed of polysilicon, and active layers of the first and third transistors STR1 and STR3, which are formed as N-type MOSFETs, may be formed of an oxide semiconductor.

The one or more embodiments corresponding to FIG. 7 differ from the one or more embodiments corresponding to FIG. 4 in that gate electrodes of the second and fourth transistors STR2 and STR4 are connected to a write scan line GWL, and a gate electrode of the first transistor STR1 is connected to a control scan line GCL. As the first and third transistors STR1 and STR3 are formed as N-type MOSFETs, a scan signal having a gate-high voltage may be applied to the control scan line GCL and the initialization scan line GIL. On the contrary, as the second, fourth, fifth, and sixth transistors STR2, STR4, STR5, and STR6 are formed as P-type MOSFETs, a scan signal having a gate-low voltage may be applied to the write scan line GWL and an emission line EL.

The pixels PX are not particularly limited to the equivalent circuit diagrams of FIGS. 5 through 7, and may also be formed in other well-known circuit configurations that can be employed by one of ordinary skill in the art to which the present disclosure pertains.

The common circuit unit CXC may be located in the non-display area NDA. The common circuit unit CXC may correspond to a common contact electrode 114, and may be connected to a second semiconductor layer SEM2, which is connected in common to a plurality of light-emitting elements LE.

The pixel electrodes 111 may be located on their respective pixel circuit units PXC. The pixel electrodes 111 may be electrodes exposed from their respective pixel circuit units PXC. The pixel electrodes 111 may be integrally formed with their respective pixel circuit units PXC. The pixel electrodes 111 may receive a pixel voltage or an anode voltage from the pixel circuit units PXC. The pixel electrodes 111 may include at least one of gold (Au), copper (Cu), tin (Sn), and silver (Ag). For example, the pixel electrodes 111 may include a 9:1 Au—Sn alloy, an 8:2 Au—Sn alloy, a 7:3 Au—Sn alloy, or a Cu—Ag—Sn alloy (e.g., SAC305).

The common electrode 112 may be located in a first common voltage supply area CVA1 of the non-display area NDA. The common electrode 112 may surround the display area DA. The common electrode 112 may be connected to one of the first pads PD1 of the first pad unit PDA1 through the common circuit unit CXC, which is formed in the non-display area NDA, to receive a common electrode. The common electrode 112 may include the same material as the pixel electrodes 111. That is, the common electrode 112 and the pixel electrodes 111 may be formed by the same process.

The contact electrodes 113 may be located on their respective pixel electrodes 111. The contact electrodes 113 may include a metallic material for bonding the pixel electrodes 111 and the light-emitting elements LE. For example, the contact electrodes 113 may include at least one of Au, Cu, aluminum (Al), and Sn. Alternatively, the contact electrodes 113 may include first layers, which include one of Au, Cu, Al, and Sn, and second layers, which include another one of Au, Cu, Al, and Sn.

The common contact electrode 114 may be located on the common electrode 112 in the non-display area NDA, and may surround the display area DA. The common contact electrode 114 may be connected to one of the first pads PD1 of the first pad unit PDA1 through the common circuit unit CXC to receive a common voltage. The common contact electrodes 114 may include the same material as the contact electrodes 113. The common contact electrodes 114 may electrically connect a power line of the common circuit unit CXC and a common connecting electrode 127 of the light-emitting element layer 120.

The first pads PD1 may be connected to pad electrodes CPD of a circuit board CB through conductive connecting members, such as wires WR. That is, the first pads PD1, the wires WR, and the pad electrodes CPD of the circuit board CB may be connected one-to-one to one another.

The circuit board CB may be a flexible printed circuit board (FPCB), a printed circuit board (PCB), a flexible printed circuit (FPC), or a flexible film, such as a chip-on-film (COF).

The second pads PD2 of the second pad unit PDA2 may be substantially the same as the first pads PD1, and thus, a repeated description thereof will be omitted.

The light-emitting element layer 120 may include the light-emitting elements LE, an insulating layer INS1, connecting electrodes 126, the common connecting electrode 127, and a first reflective layer RF1.

The light-emitting element layer 120 may include first emission areas EA1, second emission areas EA2, and third emission areas EA3, which correspond to the first light-emitting elements LE1, the second light-emitting elements LE2, and the third light-emitting elements LE3, respectively. The first light-emitting elements LE1, the second light-emitting elements LE2, and the third light-emitting elements LE3 may correspond one-to-one to the first light-emitting elements LE1, the second light-emitting elements LE2, and the third light-emitting elements LE3, respectively.

The light-emitting elements LE may correspond to their respective pixel electrodes 111 in the first emission areas EA1, the second emission areas EA2, or the third emission areas EA3. The light-emitting elements LE may be vertical LEDs extending in the third direction DR3. That is, the length of the light-emitting elements LE in the third direction DR3 may be greater than the length of the light-emitting elements LE in a horizontal direction. Here, the horizontal direction may refer to the first or second direction DR1 or DR2. For example, the length, in the third direction DR3, of the light-emitting elements LE may be about 1 µm to about 5 µm.

The light-emitting elements LE may be microLEDs. Referring to FIG. 10, a light-emitting element LE may include a connecting electrode 126, a first semiconductor layer SEM1, an electron blocking layer EBL, an active layer MQW, a superlattice layer SLT, a second semiconductor layer SEM2, and a third semiconductor layer SEM3. The connecting electrode 126, the first semiconductor layer SEM1, the electron blocking layer EBL, the active layer MQW, the superlattice layer SLT, the second semiconductor layer SEM2, and the third semiconductor layer SEM3 may be sequentially stacked in the third direction DR3.

As illustrated in FIG. 10, the light-emitting element LE may have a cylindrical, disk or rod shape having a larger width than its height, but the present disclosure is not limited thereto. Alternatively, the light-emitting element LE may have various other shapes, such as a wire or tube shape, a polygonal prism shape (e.g., a cube, a cuboid, or a hexagonal prism), or a shape extending in one direction with partially inclined outer surfaces.

The connecting electrode 126 may be located on (e.g., above) a pixel electrode 111 and a contact electrode 113. The connecting electrode 126 may be in contact with the contact electrode 113 to apply an emission signal to the light-emitting element LE. The light-emitting element LE may include at least one connecting electrode 126. FIG. 10 illustrates that the light-emitting element LE includes one connecting electrode 126, but the present disclosure is not limited thereto. Alternatively, the light-emitting element LE may include more than one connecting electrode 126, or the connecting electrode 126 may not be provided. The following description of the light-emitting element LE may be directly applicable to various other modifications of the light-emitting element LE, regardless of the number of connecting electrodes 126 provided in each of the light-emitting elements LE.

The connecting electrode 126 may be located between the contact electrode 113 and the first semiconductor layer SEM1. The connecting electrode 126 may be an ohmic connecting electrode, but the present disclosure is not limited thereto. Alternatively, the connecting electrode 126 may be a Schottky connecting electrode. The connecting electrode 126 may reduce the resistance between the light-emitting element LE and the contact electrode 113 when the light-emitting element LE is electrically connected to the contact electrode 113. The connecting electrode 126 may include a conductive metal. For example, the connecting electrode 126 may include at least one of Au, Cu, Sn, titanium (Ti), Al, and Ag. For example, the connecting electrode 126 may include a 9:1 Au—Sn alloy, an 8:2 Au—Sn alloy, a 7:3 Au—Sn alloy, or a Cu—Ag—Sn alloy (e.g., SAC305).

The first semiconductor layer SEM1 may be located on the connecting electrode 126. The first semiconductor layer SEM1 may include a p-type semiconductor (e.g., AlₓGa_{y}ln_{1-x-y}N, where 0≤x≤1, 0≤y≤1, and 0≤x+y≤1). For example, the first semiconductor layer SEM1 may include at least one of AlGalnN, GaN, AlGaN, InGaN, AlN, and InN that are doped with a p-type dopant. The first semiconductor layer SEM1 may be doped with a p-type dopant, such as Mg, Zn, Ca, Se, or Ba. For example, the first semiconductor layer SEM1 may include p-GaN doped with Mg, which is a p-type dopant. The first semiconductor layer SEM1 may have a thickness of about 30 nm to about 200 nm, but the present disclosure is not limited thereto.

The electron blocking layer EBL may be located on the first semiconductor layer SEM1. The electron blocking layer EBL may be a layer for suppressing or preventing the flow of too many electrons into the active layer MQW. For example, the electron blocking layer EBL may be p-AlGaN doped with Mg, which is a p-type dopant. The electron blocking layer EBL may have a thickness of about 10 nm to about 50 nm, but the present disclosure is not limited thereto. The electron blocking layer EBL may not be provided.

The active layer MQW may be located on the electron blocking layer EBL. The active layer MQW may emit light through the combination of electron-hole pairs in accordance with electric signals applied thereto from the first and second semiconductor layers SEM1 and SEM2. The active layer MQW may emit the first light (e.g., blue-wavelength light) or the second light (e.g., green-wavelength light).

The active layer MQW may include a material having a single- or multi-quantum well structure. In a case where the active layer MQW includes a material having a multi-quantum well structure, the active layer MQW may have a structure in which a plurality of well layers and a plurality of barrier layers are alternately stacked. The well layers may be formed of, but are not limited to, InGaN, and the barrier layers may be formed of, but are not limited to, AlGaN. The thickness of the well layers may be about 1 nm to about 4 nm, and the thickness of the barrier layers may be about 3 nm to about 10 nm.

Alternatively, the active layer MQW may have a structure in which semiconductor materials having a large bandgap energy, and semiconductor materials having a small bandgap energy, are alternately stacked, or may include a group III semiconductor material or a group V semiconductor material depending on the wavelength range of light to be emitted by the active layer MQW. The active layer MQW may emit the first light, or may emit the second light or the third light. In a case where the active layer MQW includes In, the color of light emitted by the active layer MQW may vary depending on the In content of the active layer MQW. For example, when the In content of the active layer MQW is about 10% to about 15%, the active layer MQW may emit blue-wavelength light, when the In content of the active layer MQW is about 20% to about 25%, the active layer MQW may emit green-wavelength light, and when the In content of the active layer MQW is about 30% to about 45%, the active layer MQW may emit red-wavelength light.

The superlattice layer SLT may be located on the active layer MQW. The superlattice layer SLT may be a layer for alleviating the stress between the second semiconductor layer SEM2 and the active layer MQW. For example, the superlattice layer SLT may be formed of InGaN or GaN. A thickness Tslt of the superlattice layer SLT may be about 50 nm to about 200 nm. The superlattice layer SLT may be omitted in one or more other embodiments.

The second semiconductor layer SEM2 may be located on the superlattice layer SLT. The second semiconductor layer SEM2 may include an n-type semiconductor (e.g., AlₓGa_{y}ln_{1-x-y}N, where 0≤x≤1, 0≤y≤1, and 0≤x+y≤1). For example, the second semiconductor layer SEM2 may include at least one of AlGalnN, GaN, AlGaN, InGaN, AlN, and InN that are doped with an n-type dopant. The second semiconductor layer SEM2 may be doped with an n-type dopant, such as Si, Se, or Sn. For example, the second semiconductor layer SEM2 may include n-GaN doped with Si, which is an n-type dopant. The second semiconductor layer SEM2 may have a thickness of about 2 nm to about 4 nm, but the present disclosure is not limited thereto.

The second semiconductor layer SEM2 may be a common layer connected in common to a plurality of light-emitting elements LE, as illustrated in FIG. 4. At least parts of the second semiconductor layer SEM2 may be patterned in the third direction DR3 to be located in the light-emitting elements LE, and the rest of the second semiconductor layer SEM2 may continuously extend in the first direction DR1 to be located in common on the light-emitting elements LE. The second semiconductor layer SEM2 may allow a common voltage applied through the common connecting electrode 127 to be applied in common to the light-emitting elements LE.

The third semiconductor layer SEM3, like the second semiconductor layer SEM2, may be located as a common layer. However, as the third semiconductor layer SEM3 has no conductivity, signals can be applied through the second semiconductor layer SEM2, which has conductivity. The second and third semiconductor layers SEM2 and SEM3 may extend from the display area into the non-display area NDA.

The third semiconductor layer SEM3 may be located on the second semiconductor layer SEM2. The third semiconductor layer SEM3 may include an undoped semiconductor. The third semiconductor layer SEM3 may include the same material as the second semiconductor layer SEM2, for example, a material not doped with an n- or p-type dopant. The third semiconductor layer SEM3 may include at least one of InAlGaN, GaN, AlGaN, InGaN, AlN, and InN that are not doped, but the present disclosure is not limited thereto.

The third semiconductor layer SEM3 may be a common layer connected in common to a plurality of light-emitting elements LE. The third semiconductor layer SEM3 may continuously extend in the first direction DR1 to be located in common in each of the light-emitting elements LE. The third semiconductor layer SEM3 may function as a base layer for each of the light-emitting elements LE. During the fabrication of the light-emitting element layer 120, layers that form the light-emitting elements LE may be formed on the third semiconductor layer SEM3 so that the third semiconductor layer SEM3 may function as a base layer.

The common connecting electrode 127 may be located in the first common voltage supply area CVA1 of the non-display area NDA. The common connecting electrode 127 may be located on one side of the second semiconductor layer SEM2. The common connecting electrode 127 may receive a common voltage signal for the light-emitting elements LE from the common contact electrode 114. The common connecting electrode 127 may be formed of the same material as the connecting electrodes 126. The common connecting electrode 127 may be formed to be relatively thick in the third direction DR3 to be connected to the common contact electrode 114.

The light-emitting elements LE may receive a pixel voltage or an anode voltage from the pixel electrodes 111 through the connecting electrodes 126, and may receive a common voltage through the second semiconductor layer SEM2. The light-emitting elements LE may emit light at a luminance (e.g., a predetermined luminance) in accordance with the difference between the pixel voltage and the common voltage.

The insulating layer INS1 may be located on the sides and the top (e.g., bottom) surface of the second semiconductor layer SEM2, the sides of each of the light-emitting elements LE, and the sides of each of the connecting electrodes 126. The insulating layer INS1 may insulate the second semiconductor layer SEM2, the light-emitting elements LE, and the connecting electrodes 126 from other layers.

Referring to FIG. 8, the insulating layer INS1 may surround the light-emitting elements LE. The insulating layer INS1 may include an inorganic insulating material, such as silicon oxide (SiOₓ), silicon nitride (SiNₓ), silicon oxynitride (SiOₓN_{y}), aluminum oxide (AlₓO_{y}), or aluminum nitride (AlN). The thickness of the insulating layer INS1 may be about 0.1 µm, but the present disclosure is not limited thereto.

First reflective layers RF1 may reflect light traveling sideways, among beams of light emitted from the light-emitting elements LE. The first reflective layers RF1 may be located in the display area DA. The first reflective layers RF1 may be located in the display area DA to overlap with the first emission areas EA1, the second emission areas EA2, or the third emission areas EA3.

The first reflective layers RF1 may be located on the sides of each of the connecting electrodes 126 and on the sides of each of the light-emitting elements LE (e.g., with the insulating layer INS1 at least partially therebetween). The first reflective layers RF1 may be located directly on the insulating layer INS1 and the sides of the insulating layer INS1. The first reflective layers RF1 be located to be spaced apart from the connecting electrodes 126 and the light-emitting elements LE. The first reflective layer RF1 may be partly located on the side of the connecting electrode 126.

Referring to FIG. 9, the first reflective layers RF1 may surround the light-emitting elements LE, or portions thereof, in the display area DA. Each of the light-emitting elements LE may be surrounded by the insulating layer INS1, and the insulating layer INS1 may be surrounded (e.g., partially surrounded) by the first reflective layers RF1. The first reflective layers RF1 may be spaced apart from one another. For example, the first reflective layers RF1 may be spaced apart from one another in the first and second directions DR1 and DR2. The first reflective layers RF1 and the insulating layer INS1 are illustrated as having a closed circular loop shape in a plan view, but the present disclosure is not limited thereto. That is, the first reflective layers RF1 may have various shapes depending on the shape of the light-emitting elements LE.

The first reflective layers RF1 may include a metallic material with high reflectance, such as Al. The thickness of the first reflective layer RF1 may be about 0.1 µm, but the present disclosure is not limited thereto.

The light-emitting element layer 120 and the semiconductor circuit substrate 100 may be bonded together to form the display panel 10. For example, the connecting electrodes 126 of the light-emitting elements LE of the light-emitting element layer 120, and the contact electrodes 113 of the semiconductor circuit substrate 100, may be bonded together, and the common connecting electrode 127 of the light-emitting element layer 120, and the common contact electrode 114 of the semiconductor circuit substrate 100, may be bonded together. Then, when heat is applied after the bonding of the light-emitting element layer 120 and the semiconductor circuit substrate 100, the electrodes of the light-emitting element layer 120 and the electrodes of the semiconductor circuit substrate 100 may melt and may be fusion-bonded together. As the common connecting electrode 127 and the common contact electrode 114 are formed to be relatively large to apply a common voltage to the entire light-emitting element layer 120, large amounts of materials may melt from the interface between the common connecting electrode 127 and the common contact electrode 114, and may flow into the display area DA, causing short circuits with the light-emitting elements LE. Thus, the shape of the common connecting electrode 127 and/or the shape of the common contact electrode 114 may be adjusted to reduce amounts of materials melted and flowing during the bonding of the common connecting electrode 127 and the common contact electrode 114, thus reducing or preventing the likelihood of short circuits.

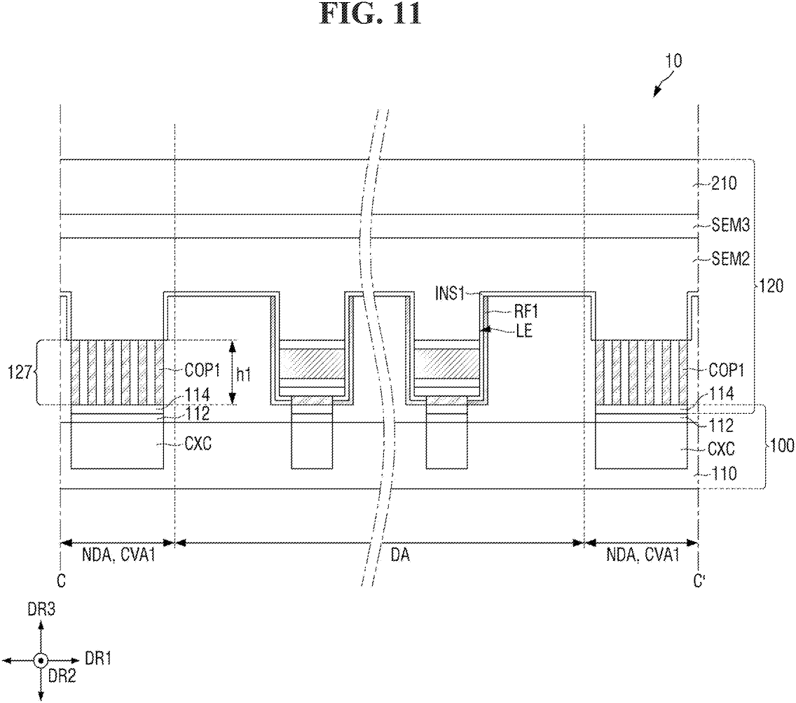

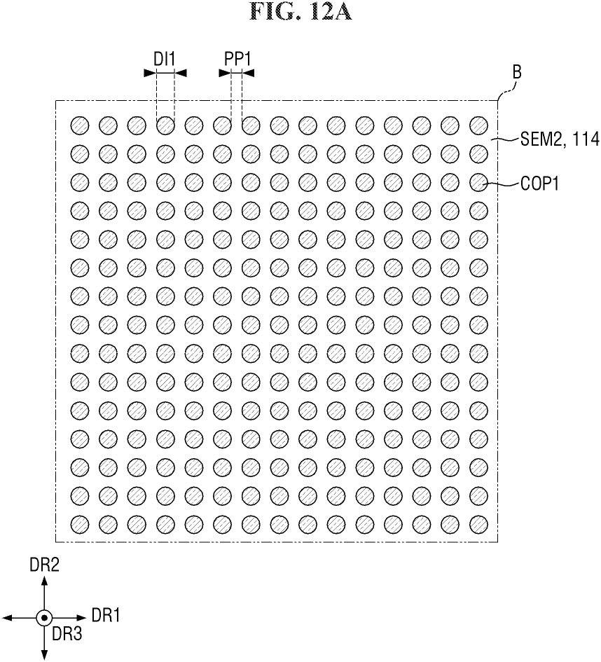

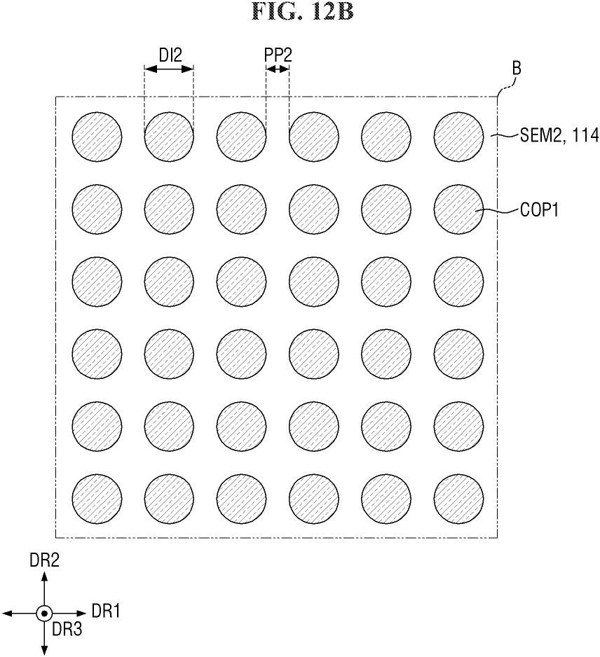

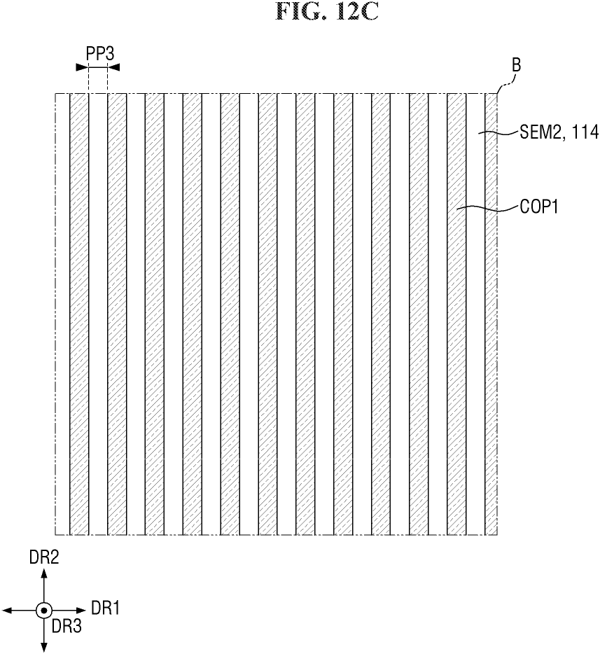

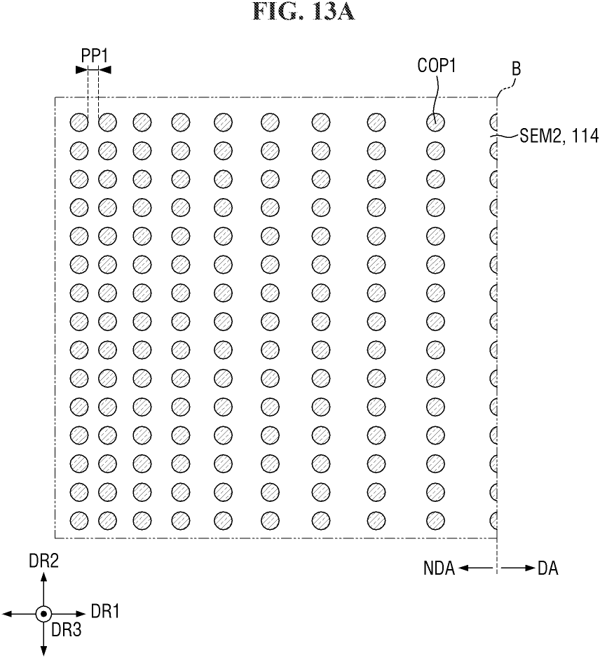

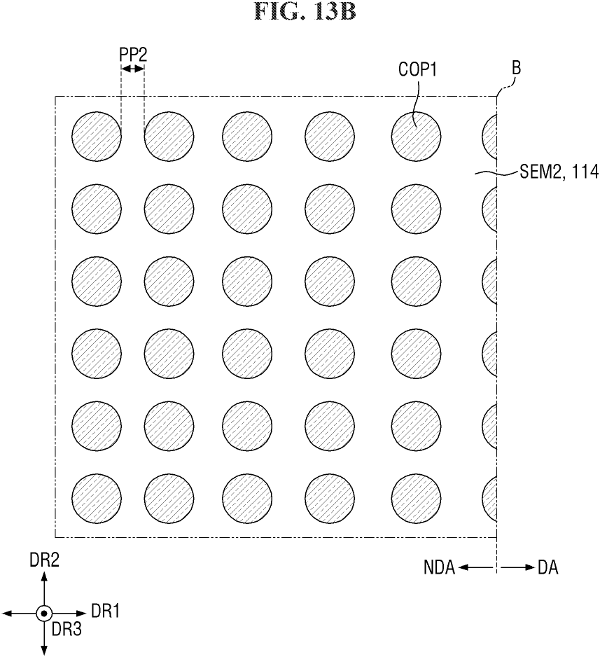

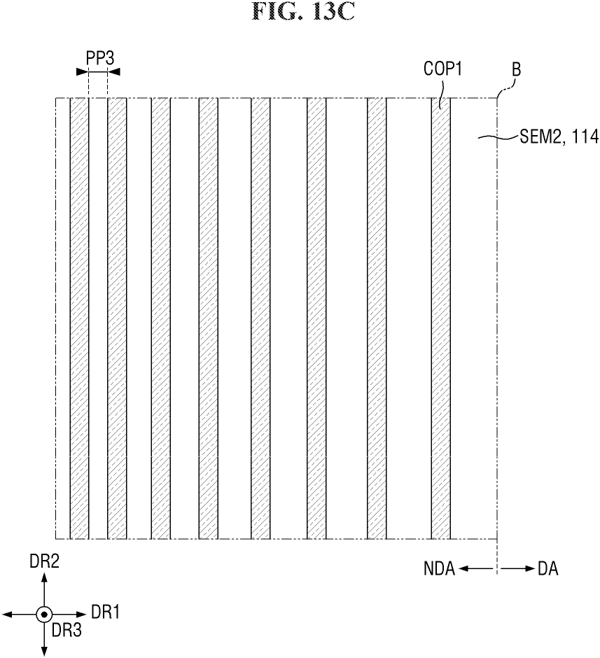

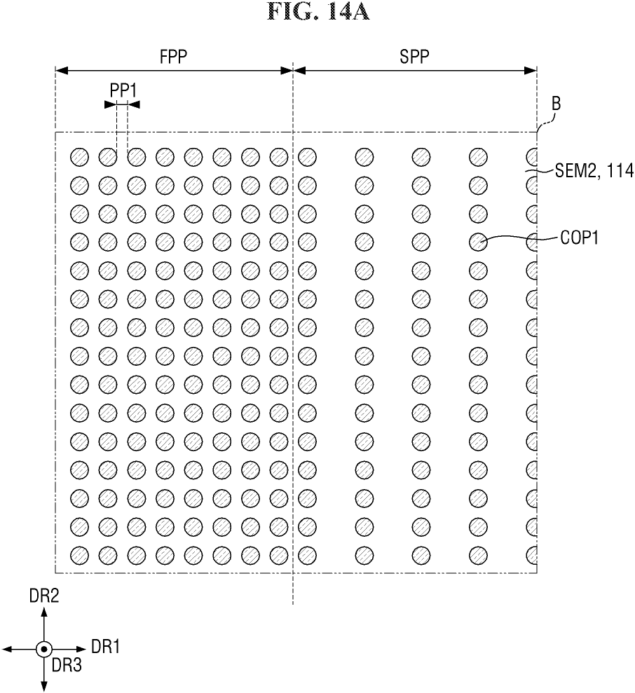

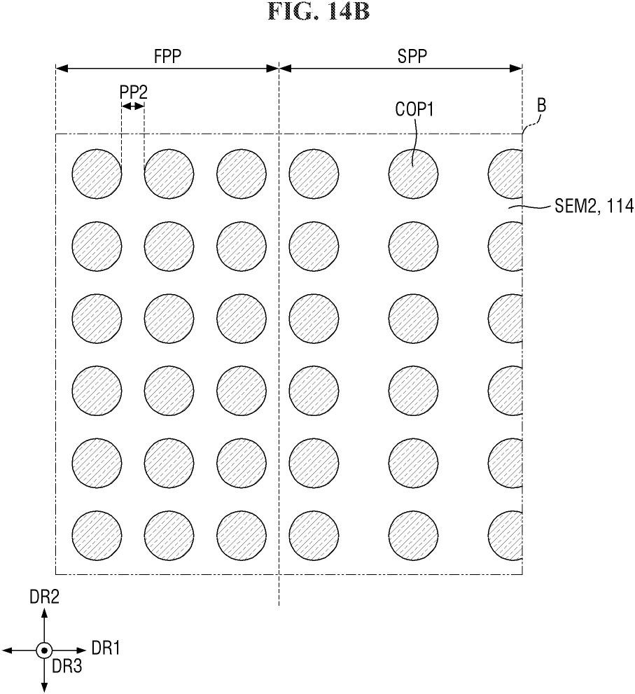

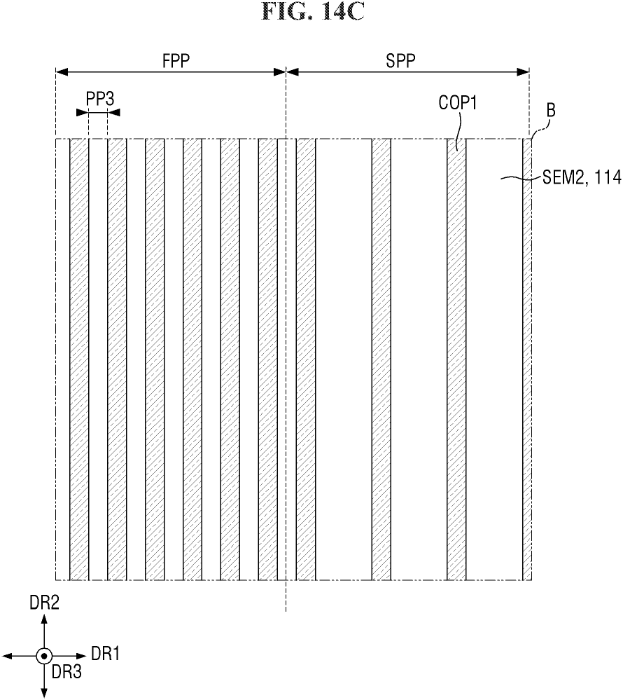

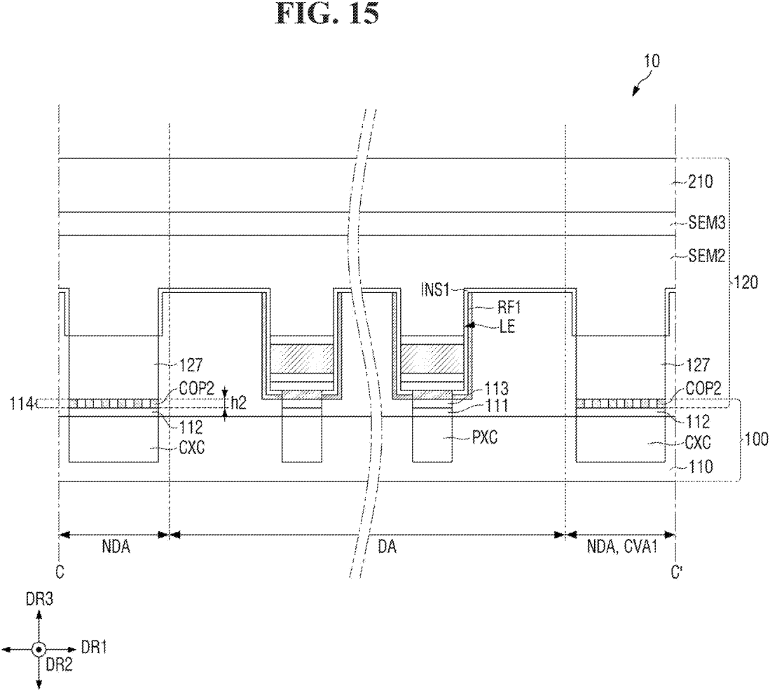

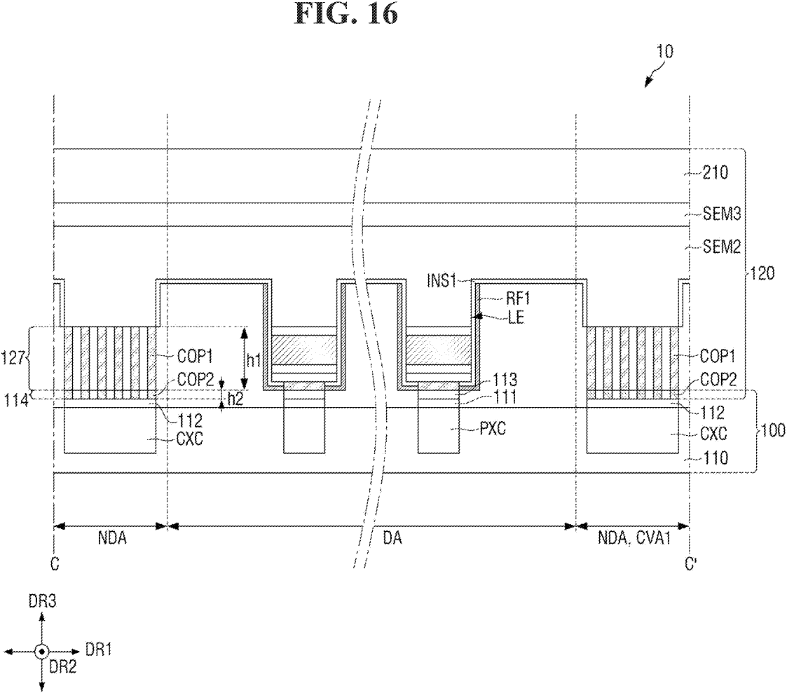

FIG. 11 is a cross-sectional view, taken along the line C-C′ of FIG. 1, of the display panel of FIG. 4, according to one or more embodiments. FIG. 12A is an enlarged layout view of the area B of FIG. 1, according to one or more embodiments. FIG. 12B is an enlarged layout view of the area B of FIG. 1, according to one or more other embodiments. FIG. 12C is an enlarged layout view of the area B of FIG. 1, according to one or more other embodiments. FIG. 13A is an enlarged layout view of the area B of FIG. 1, according to one or more other embodiments. FIG. 13B is an enlarged layout view of the area B of FIG. 1, according to one or more other embodiments. FIG. 13C is an enlarged layout view of the area B of FIG. 1, according to one or more other embodiments. FIG. 14A is an enlarged layout view of the area B of FIG. 1, according to one or more other embodiments. FIG. 14B is an enlarged layout view of the area B of FIG. 1, according to one or more other embodiments. FIG. 14C is an enlarged layout view of the area B of FIG. 1, according to one or more other embodiments. FIG. 15 is a cross-sectional view, taken along the line C-C of FIG. 1, of a display panel according to one or more other embodiments of the present disclosure. FIG. 16 is a cross-sectional view, taken along the line C-C of FIG. 1, of a display panel of the display device of FIG. 1, according to one or more other embodiments.

Referring to FIG. 11 through 14C, and further to FIG. 1, the light-emitting element layer 120 of the display panel 10 may include the common connecting electrode 127, which includes a plurality of first conductive patterns COP1.

The common connecting electrode 127 may be located in the non-display area NDA, which is located around the display area DA. The common connecting electrode 127 may surround the display area DA. The common connecting electrode 127 may be located on the bottom surface of the second semiconductor layer SEM2 of the light-emitting element layer 120 to correspond to the common circuit unit CXC of the semiconductor circuit substrate 100.

The common connecting electrode 127 may include the first conductive patterns COP1. The first conductive patterns COP1 may be located between the second semiconductor layer SEM2 of the light-emitting element layer 120, and the common contact electrode 114 of the semiconductor circuit substrate 100. First ends of the first conductive patterns COP1 may be in contact with the second semiconductor layer SEM2, and second ends of the first conductive patterns COP1 may be in contact with the common contact electrode 114. The conductive patterns COP1 may include the same material as the connecting electrodes 126, which are connected to the light-emitting elements LE.

As the common connecting electrode 127 consists of multiple first conductive patterns COP1, the area of contact between the common connecting electrode 127 and the common contact electrode 114 can be reduced, and the amount by which the common connecting electrode 127 melts while being bonded to the common contact electrode 114 by applying heat can be reduced. As a result, the amounts of materials melted and flowing into the display area DA during the bonding of the common connecting electrode 127 and the common contact electrode 114 can be reduced, and the likelihood of short circuits with the light-emitting elements LE can be reduced or prevented.

The first conductive patterns COP1 may be spaced apart from one another in the first and second directions DR1 and DR2, and the diameter of, and the distance between, the first conductive patterns COP may be adjusted.

Referring to FIG. 12A, the first conductive patterns COP1 may have a first diameter Dl1 and may be spaced apart from one another by a first distance PP1. The first conductive patterns COP1 may have a dot shape in a plan view. The first conductive patterns COP1 may be formed as circular, elliptical, or polygonal (e.g., triangular or rectangular) dots in a plan view, but the present disclosure is not limited thereto. The first conductive patterns COP1 may all have the same shape, but the present disclosure is not limited thereto. Alternatively, the first conductive patterns COP1 may have different shapes.

Alternatively, referring to FIG. 12B, the first conductive patterns COP1 may have a second diameter Dl2 and may be spaced apart from one another by a second distance PP2. The second diameter Dl2 may be greater than the first diameter Dl1 of FIG. 12A. Also, the second distance PP2 may be greater than the first distance PP1 of FIG. 12A.

Alternatively, referring to FIG. 12C, the first conductive patterns COP1 may have a linear shape. The width of, and the distance between, the first conductive patterns COP1 may be uniform, but the present disclosure is not limited thereto. Alternatively, the width of, and the distance between, the first conductive patterns COP1 may vary from one area to another area.

Alternatively, the distance between the first conductive patterns COP1 may gradually increase with increasing proximity to the display area DA.

Referring to FIG. 13A, the first distance PP1 between the first conductive patterns COP1 may gradually increase as they get closer to the display area DA. Also, referring to FIG. 13B, the second distance PP2 between the first conductive patterns COP1 may gradually increase closer to the display area DA. Also, referring to FIG. 13C, a third distance PP3 between the first conductive patterns COP1 may gradually increase closer to the display area DA. Referring to FIGS. 13A through 13C, the density of first conductive patterns COP1 may gradually decrease with increasing proximity to the display area DA.

If the distance between the first conductive patterns COP1 gradually increases closer to the display area DA, the density of first conductive patterns COP1 may gradually decrease, and the amounts of materials melted and flowing into the display area DA during the bonding of the common connecting electrode 127 and the common contact electrode 114 can be further reduced.

Referring to FIG. 14A, the non-display area NDA may include a first area FPP, which is spaced apart from the display area DA, and a second area SPP, which is located between the first area FPP and the display area DA. The second area SPP may be relatively close to the display area DA in the first direction D1, and the first area FPP may be further than the second area SPP from the display area DA.

The first distance PP1 between the first conductive patterns COP1 may be less in the first area FPP than in the second area SPP. Also, referring to FIG. 14B, the second distance PP2 between the first conductive patterns COP1 may be less in the first area FPP than in the second area SPP. Also, referring to FIG. 14C, the third distance PP3 between the first conductive patterns COP1 may be less in the first area FPP than in the second area SPP.

Referring to FIGS. 14A through 14C, the density of first conductive patterns COP1 in an area that is relatively close to the display area DA may be higher than the density of first conductive patterns COP in an area that is further from the display area DA. As the density of first conductive patterns COP1 in the area close to the display area DA is relatively low, the amounts of materials melted and flowing into the display area DA during the bonding of the common connecting electrode 127 and the common contact electrode 114 can be further reduced.

A height h1 (e.g., see FIG. 16) of the first conductive patterns COP1 may be defined as the distance between the second semiconductor layer SEM2 and the common contact electrode 114. For example, the distance between the bottom surface of the second semiconductor layer SEM2 and the top surface of the common contact electrode 114 may correspond to the height h1 of the first conductive patterns COP1. The first conductive patterns COP1 may all have the same height h1.

As the common connecting electrode 127 includes the first conductive patterns COP1, the area of contact of the common connecting electrode 127 and the common contact electrode 114 can be reduced. The first conductive patterns COP1 may account for about 10% to about 50% of the total area of the common contact electrode 114. If the first conductive patterns COP1 account for about 10% or greater of the total area of the common contact electrode 114, the common voltage applied through the common contact electrode 114 can be properly transmitted to the light-emitting elements LE. If the first conductive patterns COP1 account for about 50% or less of the total area of the common contact electrode 114, the amounts of materials melted and flowing into the display area DA during the bonding of the common connecting electrode 127 and the common contact electrode 114 can be reduced so that the likelihood of short circuits with the light-emitting elements LE can be reduced or prevented.

Referring to FIG. 15, the common contact electrode 114 may include a plurality of second conductive patterns COP2 to reduce the amounts of materials melted and potentially flowing into the display area DA during the bonding of the common connecting electrode 127 and the common contact electrode 114.

In the one or more embodiments corresponding to FIG. 15, unlike in the one or more embodiments corresponding to FIG. 11, the common contact electrode 114 may include the second conductive patterns COP2.

The common contact electrode 114 may be located on the common electrode 112 in the non-display area NDA to surround the display area DA. The common contact electrode 114 may be located on the top surface of the common electrode 112 of the semiconductor circuit substrate 100 to correspond to the common connecting electrode 127 of the light-emitting element layer 120.

The common contact electrode 114 may include the second conductive patterns COP2. The second conductive patterns COP2 may be located between the common connecting electrode 127 of the light-emitting element layer 120 and the common electrode 112 of the semiconductor circuit substrate 100. First ends of the second conductive patterns COP2 may be in contact with the common connecting electrode 127, and second ends of the second conductive patterns COP2 may be in contact with the common electrode 112.

As the common contact electrode 114 consists of multiple second conductive patterns COP2, the area of contact between the common connecting electrode 127 and the common contact electrode 114 can be reduced, and the amount by which the common contact electrode 114 melts while being bonded to the common connecting electrode 127 by applying heat can be reduced. As a result, the amounts of materials melted and flowing into the display area DA during the bonding of the common connecting electrode 127 and the common contact electrode 114 can be reduced, and short circuits with the light-emitting elements LE can be reduced or prevented.

The second conductive patterns COP2, like the first conductive patterns COP1, may be spaced apart from one another in the first and second directions DR1 and DR2. The second conductive patterns COP2 may have a dot shape or a linear shape in a plan view. The second conductive patterns COP2 may be formed as circular, elliptical, or polygonal (e.g., triangular or rectangular) dots in a plan view, but the present disclosure is not limited thereto.

A height h2 of the second conductive patterns COP2 may be defined as the distance between the common connecting electrode 127 and the common electrode 112. For example, the distance between the bottom surface of the common connecting electrode 127 and the top surface of the common electrode 112 may correspond to the height h2 of the second conductive patterns COP2. The second conductive patterns COP2 may all have the same height h2.

As the common contact electrode 114 includes the second conductive patterns COP2, the area of contact of the common connecting electrode 127 and the common contact electrode 114 can be reduced. The second conductive patterns COP2 may account for about 10% to about 50% of the total area of the common connecting electrode 127. If the second conductive patterns COP2 account for about 10% or greater of the total area of the common connecting electrode 127, the common voltage applied through the common contact electrode 114 can be properly transmitted to the light-emitting elements LE through the common connecting electrode 127. If the second conductive patterns COP2 account for about 50% or less of the total area of the common connecting electrode 127, the amounts of materials melted and flowing into the display area DA during the bonding of the common connecting electrode 127 and the common contact electrode 114 can be reduced so that short circuits with the light-emitting elements LE can be reduced or prevented.

Referring to FIG. 16, the common connecting electrode 127 may include a plurality of first conducive patterns COP1, and the common contact electrode 114 may include a plurality of second conductive patterns COP2. The first conductive patterns COP1 may be identical to the first conductive patterns COP1 of FIG. 11, and the second conductive patterns COP2 may be identical to the second conductive patterns COP2 of FIG. 15.

The first conductive patterns COP1 may overlap with the second conductive patterns COP2 in the third direction DR3. The first conductive patterns COP1 may correspond one-to-one to, and overlap one-to-one with, the second conductive patterns COP2. The first conductive patterns COP1 may be in contact with the second conductive patterns COP2. For example, the bottom surfaces of the first conductive patterns COP1 may be in contact with the top surfaces of the second conductive patterns COP2.

The first conductive patterns COP1 may have the same shape as the second conductive patterns COP2 in a plan view. A height h1 of the first conductive patterns COP1 may be greater than a height h2 of the second conductive patterns COP2, but the present disclosure is not limited thereto. Alternatively, as the second semiconductor layer SEM2 of the light-emitting element layer 120 becomes relatively thick, the height h1 of the first conductive patterns COP1 and the height h2 of the second conductive patterns COP2 may be the same, or the height h1 of the first conductive patterns COP1 may be less than the height h2 of the second conductive patterns COP2.

As the common connecting electrode 127 includes the first conductive patterns COP1 and the common contact electrode 114 includes the second conductive patterns COP2, the area of contact of the common connecting electrode 127 and the common contact electrode 114 can be reduced. The first conductive patterns COP1 or the second conductive patterns COP2 may account for about 10% to about 50% of the total area of the common electrode 112. If the first conductive patterns COP1 or the second conductive patterns COP2 account for about 10% or greater of the total area of the common electrode 112, the common voltage applied through the common electrode 112 can be properly transmitted to the light-emitting elements LE through the common contact electrode 114 and the common connecting electrode 127. If the first conductive patterns COP1 or the second conductive patterns COP2 account for about 50% or less of the total area of the common electrode 112, the amounts of materials melted and potentially flowing into the display area DA during the bonding of the common connecting electrode 127 and the common contact electrode 114 can be reduced so that short circuits with the light-emitting elements LE can be prevented.

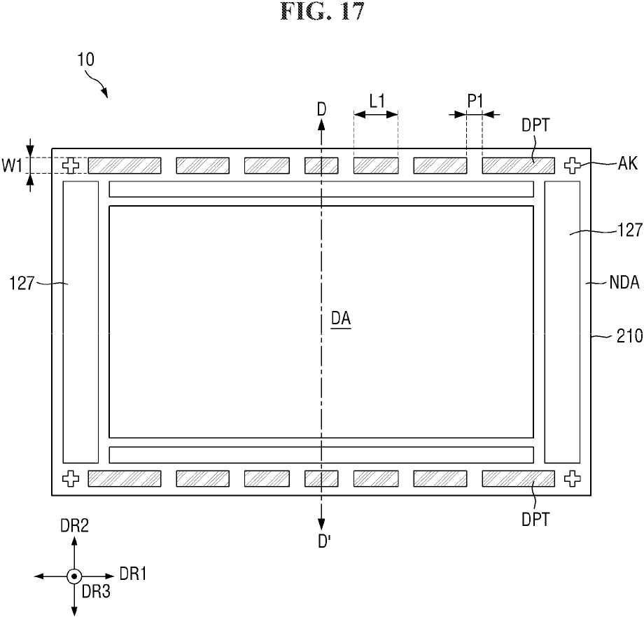

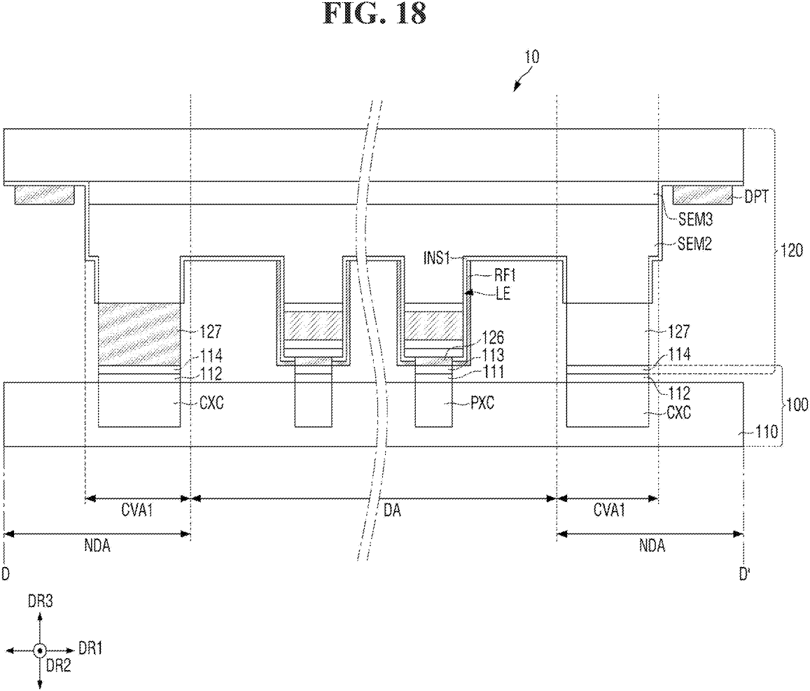

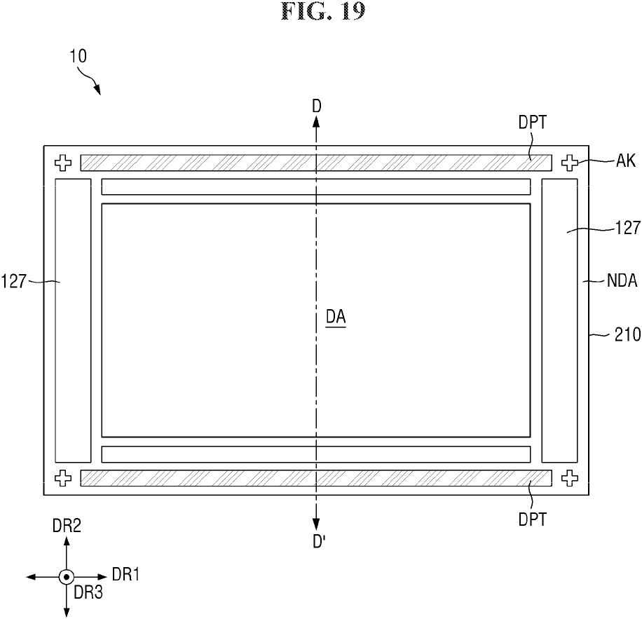

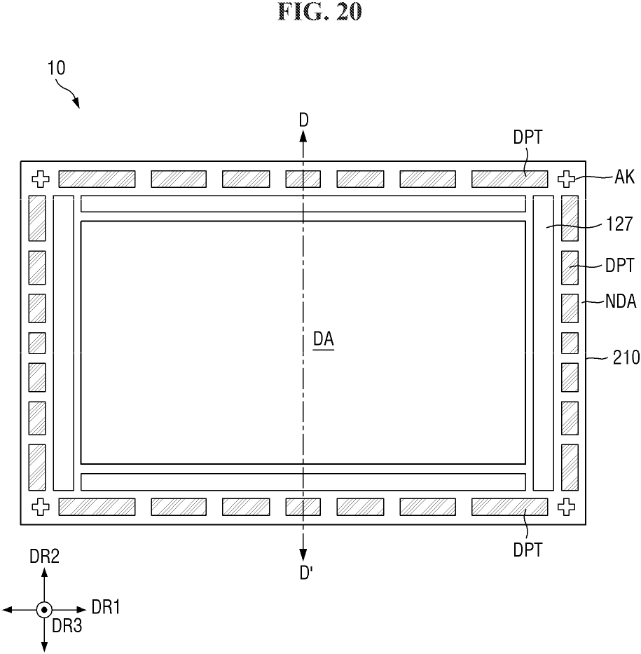

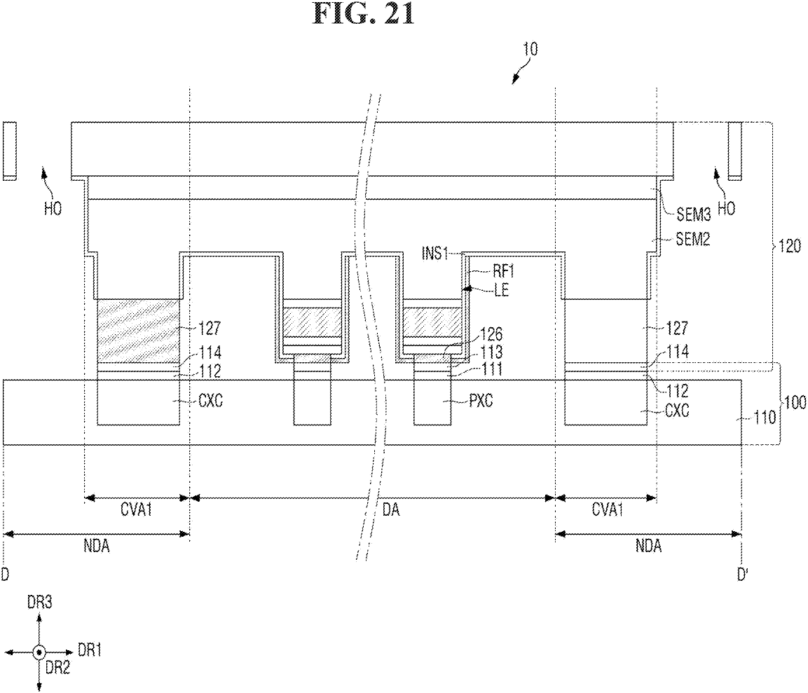

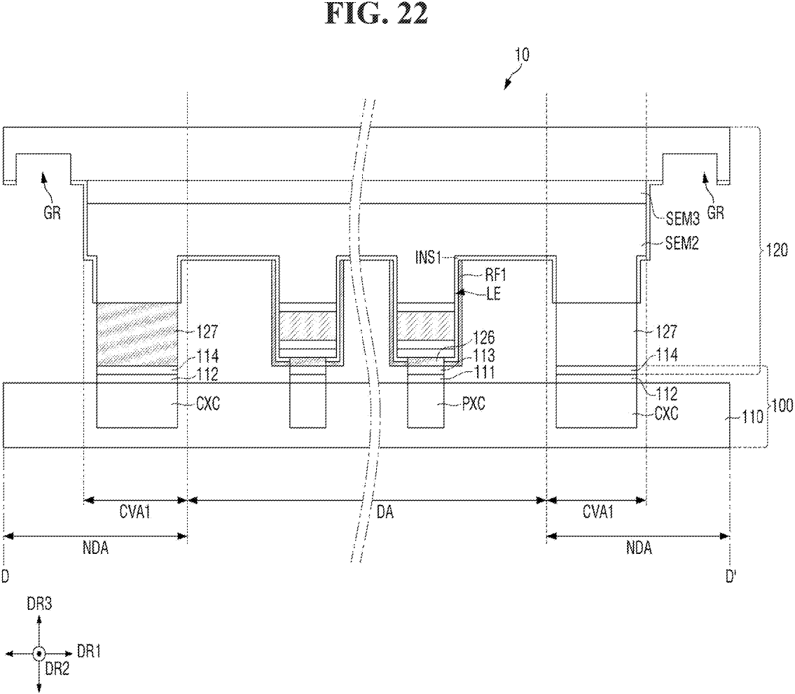

FIG. 17 is a plan view of the display panel of FIG. 4, according to one or more embodiments. FIG. 18 is a cross-sectional view taken along the line D-D′ of FIG. 17. FIG. 19 is a plan view of a display panel of the display device of FIG. 1, according to one or more other embodiments. FIG. 20 is a plan view of a display panel of the display device of FIG. 1, according to one or more other embodiments. FIG. 21 is a cross-sectional view of a display panel of the display device of FIG. 1, according to one or more other embodiments. FIG. 22 is a cross-sectional view of a display panel of the display device of FIG. 1, according to one or more other embodiments.

Referring to FIGS. 17 through 20, the display panel 10 may include the light-emitting element layer 120, which includes a second substrate 210. The light-emitting element layer 120 may include a display area DA, and a non-display area NDA that surrounds the display area DA. As already mentioned above, the common connecting electrode 127, which surrounds the display area DA, may be located in the non-display area NDA.

As described above with reference to FIGS. 4 through 10, the light-emitting element layer 120 and the semiconductor circuit substrate 100 may be aligned with each other, and may then be bonded together by thermal treatment. For example, the connecting electrodes 126 and the common connecting electrode 127 of the light-emitting element layer 120, and the contact electrodes 113 and the common contact electrode 114 of the semiconductor circuit substrate 100, may be respectively bonded together by a thermal treatment process. The thermal treatment process may be performed by bonding an upper part of the light-emitting element layer 120 and a lower part of the semiconductor circuit substrate 100 together, and then applying heat, or may be performed by applying heat from above the light-emitting element layer 120 via laser light. However, due to the difference in coefficients of thermal expansion (CTE) between silicon (Si), which forms the first substrate 110 of the semiconductor circuit substrate 100, and sapphire, which forms the second substrate 210 of the light-emitting element layer 120, the light-emitting element layer 120 and the semiconductor circuit substrate 100 may be misaligned after the thermal treatment process. For example, as sapphire has a greater CTE than the first substrate 110, the second substrate 210 may be deformed more considerably than the first substrate 110.

To reduce or prevent the deformation of the second substrate 210 of the light-emitting element layer 120, dummy patterns DPT may be further provided.

As illustrated in FIGS. 17 and 18, a plurality of dummy patterns DPT may be provided in the light-emitting element layer 120 in the non-display area NDA. The dummy patterns DPT may be located along edges of the second substrate 210, for example, along outermost parts of the second substrate 210. The dummy patterns DPT may be located along the long sides of the second substrate 210, which extend in the first direction DR1. For example, the dummy patterns DPT may be located adjacent to the upper and lower long sides of the second substrate 210. The dummy patterns DPT may be located between the upper long side of the second substrate 210 and the display area DA, for example, between the upper long side of the second substrate 210 and the common connecting electrode 127.

The dummy patterns DPT may be located on a surface of the second substrate 210 that faces the first substrate 110, for example, on the bottom surface of the second substrate 210. For example, the dummy patterns DPT may be located directly on the bottom surface of the insulating layer INS1, which is located on the bottom surface of the second substrate 210.

During the bonding of the light-emitting element layer 120 and the semiconductor circuit substrate 100, the dummy patterns DPT may release, or alleviate, heat from the second substrate 210 of the light-emitting element layer 120, and may support the second substrate 210 not to be thermally deformed. For example, the dummy patterns DPT may be heat sinks for dissipating heat from the second substrate 210. To this end, the dummy patterns DPT may include a metallic material, such as, for example, at least one of Au, Cu, Sn, Ti, Al, and Ag. The dummy patterns DPT may include the same material(s) as the connecting electrodes 126 and the common connecting electrode 127 of the light-emitting element layer 120.

The dummy patterns DPT may be spaced apart from one another in the first direction DR1. A distance P1 between the dummy patterns DPT may be uniform, but the present disclosure is not limited thereto. Alternatively, the distance P1 between the dummy patterns DPT may vary from one area to another area. The dummy patterns DPT may have a width W1 in the second direction DR2. The width W1 of the dummy patterns DPT may have its maximum between the second substrate 210 and the common connecting electrode 127 to improve the effect of heat dissipation. The width W1 of the dummy patterns DPT may be uniform, but the present disclosure is not limited thereto. Alternatively, the width W1 of the dummy patterns DPT may vary from one area to another area.

The dummy patterns DPT may have a length L1 in the first direction DR1. The length L1 may refer to the length of the long sides of the second substrate 210. The length L1 of the dummy patterns DPT may be uniform, but the present disclosure is not limited thereto. Alternatively, the length L1 of the dummy patterns DPT may vary from one area to another area.

The thermal deformation of the second substrate 210 may become relatively severe in the first direction DR1 from the long sides of the second substrate 210. For example, the thermal deformation of the second substrate 210 may become increasingly severe away from the center of each of the long sides of the second substrate 210. The length L1 of the dummy patterns DPT may gradually increase away from the center of each of the long sides of the second substrate 210. For example, the length L1 of the dummy patterns DPT may gradually increase as a distance from the center of each of the long sides of the second substrate 210 increases, and as a proximity to the short sides of the second substrate 210 increases, the short sides extending in the second direction DR2.

Dummy patterns DPT in the middle of each of the long sides of the second substrate 210 may be shortest, and dummy patterns DPT on either end of each of the long sides (e.g., near either edge of the short sides) of the second substrate 210 may be longest. That is, long dummy patterns DPT may be located on both sides of each of the long sides of the second substrate 210 where the thermal deformation of the second substrate 210 is relatively severe, and short dummy patterns DPT may be located in the middle of each of the long sides of the second substrate 210 where the thermal deformation of the second substrate 210 is relatively less severe. Accordingly, the thermal deformation of the second substrate 210 of the light-emitting element layer 120 during the bonding of the light-emitting element layer 120 and the semiconductor circuit substrate 100 can be improved, and thus, the misalignment of the light-emitting element layer 120 and the semiconductor circuit substrate 100 can be improved.

The dummy patterns DPT may be located adjacent to alignment keys AK, which are located at one or more corners of the second substrate 210. The dummy patterns DPT may include a metallic material, and may thus assist with the alignment of the light-emitting element layer 120 and the semiconductor circuit substrate 100, together with the alignment keys AK.

Referring to FIG. 19, two dummy patterns DPT (e.g., one respective dummy pattern DPT along each of the long sides of the second substrate 210), may be provided on the second substrate 210 of the light-emitting element layer 120. The length, in the first direction DR1, of the dummy patterns DPT may be greater than the length, in the first direction DR1, of the display area DA, and less than the length, in the first direction DR1, of the second substrate 210.

Referring to FIG. 20, dummy patterns DPT may be further located on the second substrate 210 of the light-emitting element layer 120 along the short sides of the second substrate 210. In the one or more embodiments corresponding to FIG. 20, like in the one or more embodiments corresponding to FIG. 17, the length of the dummy patterns DPT may gradually increase away from the center of each of the short sides of the second substrate 210, along the second direction DR2. However, the present disclosure is not limited to this. Alternatively, one dummy pattern DPT may be provided on each of the long sides and the short sides of the second substrate 210.

Referring to FIG. 21, the light-emitting element layer 120 may include a plurality of holes HO. The one or more embodiments corresponding to FIG. 21 differ from the embodiments of FIGS. 17 through 20 in that the holes HO are provided instead of the dummy patterns DPT, and the layout and the shape of the holes HO may be similar to the layout and the shape of the dummy patterns DPT. Thus, the one or more embodiments corresponding to FIG. 21 will hereinafter be described, focusing mainly on the differences with the one or more embodiments corresponding to FIGS. 17 through 20.

The holes HO may be located in the insulating layer INS1 and the second substrate 210. The holes HO may be through holes completely penetrating the insulating layer INS1 and the second substrate 210. The holes HO may expose the sides of the insulating layer INS1 and the sides of the second substrate 210. As the holes HO can release heat from the inside of the second substrate 210 of the light-emitting element layer 120 during the bonding of the light-emitting element layer 120 and the semiconductor circuit substrate 100, the thermal deformation of the second substrate 210 can be improved.

The holes HO, like the dummy patterns DPT, may be located along the long sides of the second substrate 210, along the short sides of the second substrate 210, or along both the long sides and the short sides of the second substrate 210. The length of the holes HO may gradually increase away from the center of each of the long sides/short sides of the second substrate 210.

Referring to FIG. 22, the light-emitting element layer 120 may include a plurality of grooves GR. The one or more embodiments corresponding to FIG. 22 differ from the embodiments of FIGS. 17 through 21 in that the grooves GR are provided instead of the dummy patterns DPT or the holes HO, and the layout and the shape of the grooves GR may be similar to the layout and the shape of the dummy patterns DPT or the holes HO. Thus, the one or more embodiments corresponding to FIG. 22 will hereinafter be described, focusing mainly on the differences with the one or more embodiments corresponding to FIGS. 17 through 21.

The grooves GR may be formed in the second substrate 210. The grooves GR may expose the sides of the insulating layer INS1 and the sides of the second substrate 210, through the insulating layer INS1. As the grooves GR can release heat from the inside of the second substrate 210 of the light-emitting element layer 120 during the bonding of the light-emitting element layer 120 and the semiconductor circuit substrate 100, the thermal deformation of the second substrate 210 can be improved.

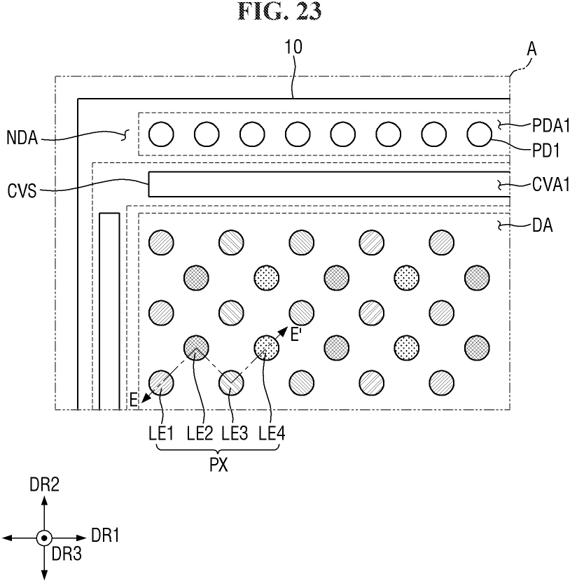

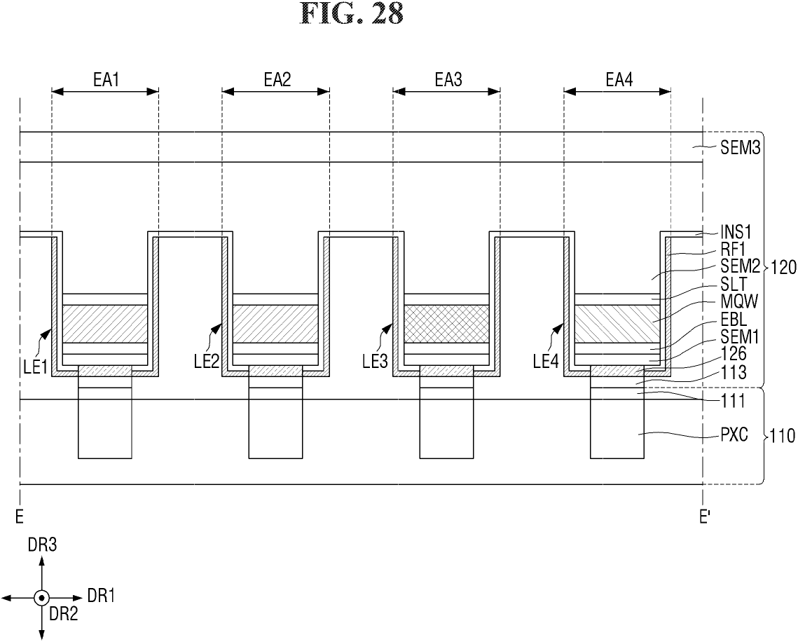

FIGS. 23 through 27 are layout views of the area A of FIG. 1, according to one or more other embodiments. FIG. 28 is a cross-sectional view taken along the line E-E′ of FIG. 23.

The one or more embodiments corresponding to FIGS. 23 and 28 differ from the one or more embodiments corresponding to FIGS. 2 and 3 in that fourth light-emitting elements LE4, which emit the same second light as the second light-emitting elements LE2, are further provided, and the first emission areas EA1, the second emission areas EA2, the third emission areas EA3, and fourth emission areas EA4 may be arranged in a PENTILE™ layout (e.g., a RGBG matrix structure, a PENTILE™ matrix structure, a PENTILE™ structure, or an RGBG structure, PENTILE™ being a registered trademark of Samsung Display Co., Ltd., Republic of Korea). The one or more embodiments corresponding to FIGS. 23 and 28 will hereinafter be described, focusing mainly on the differences with the one or more embodiments corresponding to FIGS. 2 and 3.

Referring to FIGS. 23 and 28, each of the pixels PX may include a first light-emitting element LE1, which emits the first light, a second light-emitting element LE2, which emits the second light, a third light-emitting element LE3, which emits the third light, and a fourth light-emitting element LE4, which emits the second light.

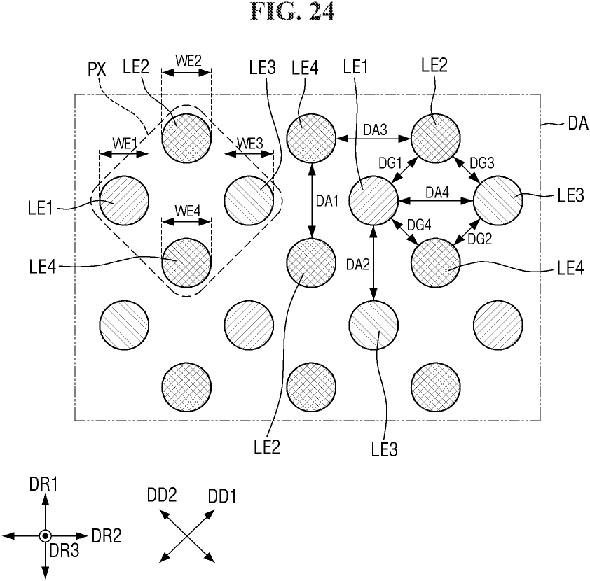

The first light-emitting elements LE1 and the third light-emitting elements LE3 may be alternately arranged in the first direction DR1 in the display area DA. The second light-emitting elements LE2 and the fourth light-emitting elements LE4 may be alternately arranged in the first direction DR1. The first light-emitting elements LE1, the second light-emitting elements LE2, the third light-emitting elements LE3, and the fourth light-emitting elements LE4 may be alternately arranged in first and second diagonal directions DD1 and DD2 (e.g., see FIG. 24). The first diagonal direction DD1 may be a diagonal direction between the first and second directions DR1 and DR2, and the second diagonal direction DD2 may be orthogonal to the first diagonal direction DD1.

In each of the pixels PX, the first and third light-emitting elements LE1 and LE3 may be arranged side-by-side in the first direction DR1, and the second and fourth light-emitting elements LE2 and LE4 may be arranged side-by-side in the first direction DR1. In each of the pixels PX, the first and second light-emitting elements LE1 and LE2 may be arranged side-by-side in the first diagonal direction DD1, the second and third light-emitting elements LE2 and LE3 may be arranged side-by-side in the second diagonal direction DD2, and the third and fourth light-emitting elements LE3 and LE4 may be arranged side-by-side in the first diagonal direction DD1.

The fourth light-emitting elements LE4 may be substantially the same as the second light-emitting elements LE2. That is, the fourth light-emitting elements LE4 may emit the second light, and may have the same structure as the second light-emitting elements LE2.

The first light-emitting elements LE1 may be located in the first emission areas EA1, the second light-emitting elements LE2 may be located in the second emission areas EA2, the third light-emitting elements LE3 may be located in the third emission areas EA3, and the fourth light-emitting elements LE4 may be located in the fourth emission areas EA4.

The size of the first emission areas EA1, the size of the second emission areas EA2, the size of the third emission areas EA3, and the size of the fourth emission areas EA4 may be substantially the same, but the present disclosure is not limited thereto. Alternatively, the size of the first emission areas EA1, the size of the second emission areas EA2, and the size of the third emission areas EA3 may differ from one another, and the size of the second emission areas EA2 and the size of the fourth emission areas EA4 may be the same.

The distance between the first emission areas EA1 and the second emission areas EA2, the distance between the second emission areas EA2 and the third emission areas EA3, the distance between the first emission areas EA1 and the fourth emission areas EA4, and the distance between the third emission areas EA3 and the fourth emission areas EA4 may be substantially the same, but the present disclosure is not limited thereto. Alternatively, the distance between the first emission areas EA1 and the second emission areas EA2 may differ from the distance between the second emission areas EA2 and the third emission areas EA3, and the distance between the first emission areas EA1 and the fourth emission areas EA4 and the distance between the third emission areas EA3 and the fourth emission areas EA4 may differ from each other. In this case, the distance between the first emission areas EA1 and the second emission areas EA2, and the distance between the first emission areas EA1 and the fourth emission areas EA4, may be substantially the same, and the distance between the second emission areas EA2 and the third emission areas EA3, and the distance between the third emission areas EA3 and the fourth emission areas EA4, may be substantially the same.

Referring to FIG. 24, each of the pixels PX may include four light-emitting elements LE (e.g., first through fourth light-emitting elements LE1 through LE4), and the first through fourth light-emitting elements LE1 through LE4 may be spaced apart from one another in the first and second directions DR1 and DR2, and each pair of adjacent light-emitting elements LE may be spaced apart from one another in the first and second diagonal directions DD1 and DD2, between the first and second directions DR1 and DR2.

The first light-emitting elements LE1, the second light-emitting elements LE2, the third light-emitting elements LE3, and the fourth light-emitting elements LE4 may have the same diameter. For example, a first diameter WE1 of the first light-emitting elements LE1, a second diameter WE2 of the second light-emitting elements LE2, a third diameter WE3 of the third light-emitting elements LE3, and a fourth diameter WE4 of the fourth light-emitting elements LE4 may all be the same. In the one or more embodiments corresponding to FIG. 3, the first light-emitting elements LE1, the second light-emitting elements LE2, and the third light-emitting elements LE3 may have the same diameter. However, the present disclosure is not limited to this. Alternatively, the light-emitting elements LE1, the second light-emitting elements LE2, the third light-emitting elements LE3, and the fourth light-emitting elements LE4 may have different diameters.

The distances between the second light-emitting elements LE2 and the fourth light-emitting elements LE4 may be the same as the distances between the first light-emitting elements LE1 and the third light-emitting elements LE3. For example, a first distance DA1, in the first direction DR1, between the second light-emitting elements LE2 and the fourth light-emitting elements LE4 may be the same as a second distance DA2, in the first direction DR1, between the first light-emitting elements LE1 and the third light-emitting elements LE3, and a third distance DA3, in the second direction DR2, between the second light-emitting elements LE2 and the fourth light-emitting elements LE4 may be the same as a fourth distance DA4, in the second direction DR2, between the first light-emitting elements LE1 and the third light-emitting elements LE3. Also, for example, a first diagonal distance DG1, in the first diagonal direction DD1, between the first light-emitting elements LE1 and the second light-emitting elements LE2 may be the same as a second diagonal distance DG2, in the first diagonal direction DD1, between the third light-emitting elements LE3 and the fourth light-emitting elements LE4, and a third diagonal distance DG3, in the second diagonal direction DD2, between the second light-emitting elements LE2 and the third light-emitting elements LE3 may be the same as a fourth diagonal distance DG4, in the second diagonal direction DD2, between the first light-emitting elements LE1 and the fourth light-emitting elements LE4. However, the present disclosure is not limited to these examples. The distances between the light-emitting elements LE may vary depending on the layout and the diameter of the light-emitting elements LE.

FIG. 24 illustrates the first through fourth distances DA1 through DA4 and the first through fourth diagonal distances DG1 through DG4 as being measured from between the circumferences (or outer sides) of the light-emitting elements LE, but the present disclosure is not limited thereto. Alternatively, the first through fourth distances DA1 through DA4 and the first through fourth diagonal distances DG1 through DG4 may be measured from between the centers of the light-emitting elements LE.

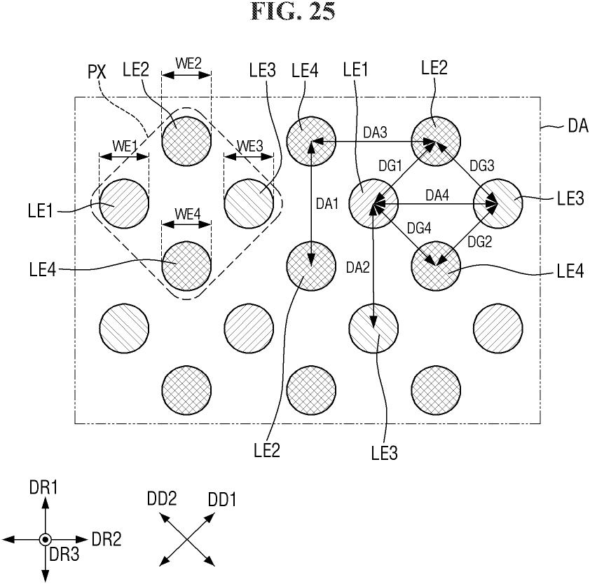

Referring to FIG. 25, the respective distances between the centers of the second light-emitting elements LE2 and the centers of the fourth light-emitting elements LE4 may be the same as the respective distances between the centers of the first light-emitting elements LE1 and the centers of the third light-emitting elements LE3. For example, a first distance DA1, in the first direction DR1, between the centers of the respective second light-emitting elements LE2 and the centers of the respective fourth light-emitting elements LE4 may be the same as a second distance DA2, in the first direction DR1, between the centers of the respective first light-emitting elements LE1 and the centers of the respective third light-emitting elements LE3, and a third distance DA3, in the second direction DR2, between the centers of the respective second light-emitting elements LE2 and the centers of the respective fourth light-emitting elements LE4 may be the same as a fourth distance DA4, in the second direction DR2, between the centers of the respective first light-emitting elements LE1 and the centers of the respective third light-emitting elements LE3. Also, for example, a first diagonal distance DG1, in the first diagonal direction DD1, between the centers of the respective first light-emitting elements LE1 and the centers of the respective second light-emitting elements LE2 may be the same as a second diagonal distance DG2, in the first diagonal direction DD1, between the centers of the respective third light-emitting elements LE3 and the centers of the respective fourth light-emitting elements LE4, and a third diagonal distance DG3, in the second diagonal direction DD2, between the centers of the respective second light-emitting elements LE2 and the centers of the third light-emitting elements LE3 may be the same as a fourth diagonal distance DG4, in the second diagonal direction DD2, between the centers of the respective first light-emitting elements LE1 and the centers of the fourth light-emitting elements LE4.

In the one or more embodiments corresponding to FIG. 25, the first through fourth distances DA1 through DA4 may all be the same, and the first through fourth diagonal distances DG1 through DG4 may all be the same. However, the present disclosure is not limited to this. Alternatively, in the one or more embodiments corresponding to FIG. 25, like in the one or more embodiments corresponding to FIG. 24, the distances between the centers of the light-emitting elements LE may vary depending on the layout and the diameter of the light-emitting elements LE.

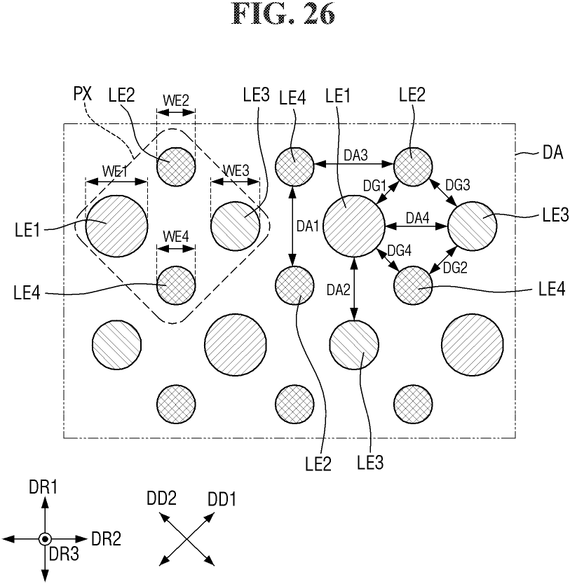

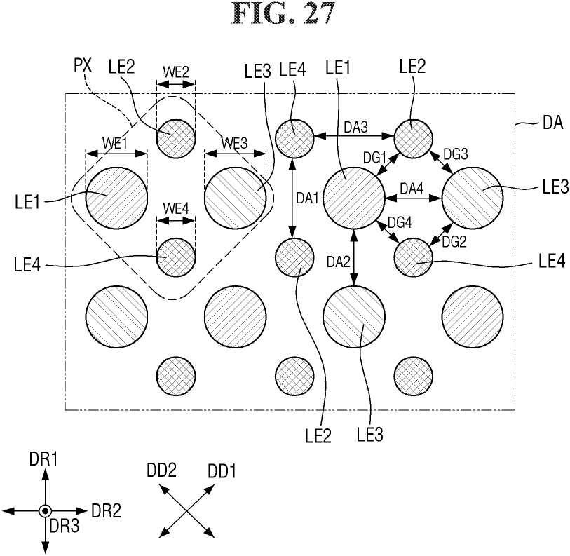

Referring to FIGS. 26 and 27, the light-emitting elements LE may have different sizes. For example, referring to FIG. 26, the first diameter WE1 of the first light-emitting elements LE1 may be greater than the second diameter WE2 of the second light-emitting elements LE2, the third diameter WE3 of the third light-emitting elements LE3, and the fourth diameter WE4 of the fourth light-emitting elements LE4. The third diameter WE3 of the third light-emitting elements LE3 may be greater than the second diameter WE2 of the second light-emitting elements LE2 and the fourth diameter WE4 of the fourth light-emitting elements LE4. The second diameter WE2 of the second light-emitting elements LE2 may be the same as the fourth diameter WE4 of the fourth light-emitting elements LE4. The one or more embodiments corresponding to FIG. 27 differ from the one or more embodiments corresponding to FIG. 26 in that the first diameter WE1 of the first light-emitting elements LE1 is the same as the third diameter WE3 of the third light-emitting elements LE3.

The distances between the light-emitting elements LE may differ from one another. For example, the first distance DA1, in the first direction DR1, between the second light-emitting elements LE2 and the fourth light-emitting elements LE4 may be greater than the second distance DA2, in the first direction DR1, between the first light-emitting elements LE1 and the third light-emitting elements LE3. The third distance DA3, in the second direction DR2, between the second light-emitting elements LE2 and the fourth light-emitting elements LE4 may be greater than the fourth distance DA4, in the second direction DR2, between the first light-emitting elements LE1 and the third light-emitting elements LE3. Also, for example, the first diagonal distance DG1, in the first diagonal direction DD1, between the first light-emitting elements LE1 and the second light-emitting elements LE2 may differ from the second diagonal distance DG2, in the first diagonal direction DD1, between the third light-emitting elements LE3 and the fourth light-emitting elements LE4. Also, the third diagonal distance DG3, in the second diagonal direction DD2, between the second light-emitting elements LE2 and the third light-emitting elements LE3 may differ from the fourth diagonal distance DG4, in the second diagonal direction DD2, between the first light-emitting elements LE1 and the fourth light-emitting elements LE4.

In one or more embodiments where the first diameter WE1 of the first light-emitting elements LE1 is greater than the third diameter WE3 of the third light-emitting elements LE3, the first diagonal distance DG1 may be less than the second diagonal distance DG2, and the third diagonal distance DG3 may be greater than the fourth diagonal distance DG4. However, the present disclosure is not limited to this. The distances between the light-emitting elements LE may vary depending on the layout and the diameter of the light-emitting elements LE. For example, in one or more embodiments where the first diameter WE1 of the first light-emitting elements LE1 is the same as the third diameter WE3 of the third light-emitting elements LE3, the first and second diagonal distances DG1 and DG2 may be the same, and the third and fourth diagonal distances DG3 and DG4 may be the same.

FIGS. 26 and 27 illustrate the first through fourth distances DA1 through DA4 and the first through fourth diagonal distances DG1 through DG4 as being measured from between the circumferences (or outer sides) of the light-emitting elements LE, but the present disclosure is not limited thereto. Alternatively, as already mentioned above with reference to FIG. 25, the first through fourth distances DA1 through DA4 and the first through fourth diagonal distances DG1 through DG4 may be measured from between the centers of the light-emitting elements LE. However, in one or more embodiments where the light-emitting elements LE have different diameters, the order of magnitude between the distances between the light-emitting elements LE may differ depending on whether the distances between the light-emitting elements LE are measured from between the circumferences (or outer sides) of the light-emitting elements LE or between the centers of the light-emitting elements LE.

The first emission areas EA1 may emit the first light, the second emission areas EA2 and the fourth emission areas EA4 may emit the second light, and the third emission areas EA3 may emit the third light. However, the present disclosure is not limited to this. Alternatively, the first emission areas EA1 may emit the first light, the second emission areas EA2 and the fourth emission areas EA4 may emit the third light, and the third emission areas EA3 may emit the second light. Alternatively, the first emission areas EA1 may emit the second light, the second emission areas EA2 and the fourth emission areas EA4 may emit the first light, and the third emission areas EA3 may emit the third light.

The first emission areas EA1, the second emission areas EA2, the third emission areas EA3, and the fourth emission areas EA4 may have a circular shape in a plan view, but the present disclosure is not limited thereto. Alternatively, the first emission areas EA1, the second emission areas EA2, the third emission areas EA3, and the fourth emission areas EA4 may have a polygonal shape (e.g., a triangular, rectangular, pentagonal, hexagonal, and octagonal shape), an elliptical shape, or an amorphous shape in a plan view.

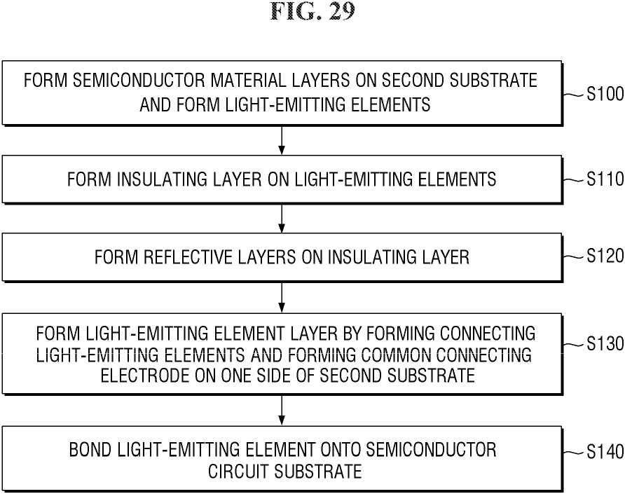

A method of fabricating the display device 1 will hereinafter be described with reference to FIGS. 29 through 37.

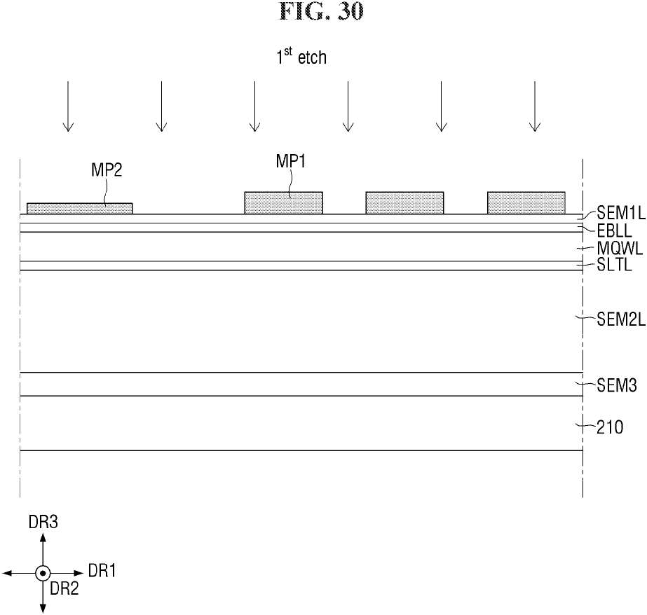

FIG. 29 is a flowchart illustrating a method of fabricating a display panel, according to one or more embodiments of the present disclosure. FIGS. 30 through 37 are cross-sectional views illustrating the method of fabricating a display panel, according to one or more embodiments of the present disclosure.

FIGS. 30 through 37 are cross-sectional views illustrating structures resulting from operations of the formation of layers of the display panel 10 of the display device 1. For example, FIGS. 30 through 37 are cross-sectional views taken along the line A-A′ of FIG. 2 and mainly illustrate how to fabricate the light-emitting element layer 120.

Referring to FIG. 29, a plurality of semiconductor material layers (e.g., SEM3, SEM2L, SLTL, MQWL, EBLL, and SEM1L) are formed on the second substrate 210 (S100).

For example, referring to FIG. 30, the second substrate 210 is prepared. The second substrate 210 may be a sapphire (Al₂O₃) substrate or a silicon wafer, but the present disclosure is not limited thereto. The second substrate 210 will hereinafter be described as being, for example, a sapphire substrate.

The semiconductor material layers (SEM3, SEM2L, SLTL, MQWL, EBLL, and SEM1L) are formed on the second substrate 210. The semiconductor material layers (SEM3, SEM2L, SLTL, MQWL, EBLL, and SEM1L) may be formed by growing seed crystals via an epitaxial method. Here, the semiconductor material layers (SEM3, SEM2L, SLTL, MQWL, EBLL, and SEM1L) may be formed by electron beam deposition, physical vapor deposition (PVD), chemical vapor deposition (CVD), plasma laser deposition (PLD), dual-type thermal evaporation, sputtering, or metal-organic chemical vapor deposition (MOCVD), but the present disclosure is not limited thereto.

A precursor material for forming the semiconductor material layers (SEM3, SEM2L, SLTL, MQWL, EBLL, and SEM1L) is not particularly limited. For example, the precursor material may be a metal precursor including an alkyl group, such as a methyl or ethyl group. For example, the precursor material may be a compound, such as trimethyl gallium (Ga(CH₃)₃), trimethyl aluminum (Al(CH₃)₃), or triethyl phosphate ((C₂H₅)₃PO₄), but the present disclosure is not limited thereto.

For example, the third semiconductor layer SEM3 is formed on the second substrate 210. The third semiconductor layer SEM3 is illustrated as being a single layer, but the present disclosure is not limited thereto. Alternatively, the third semiconductor layer SEM3 may be formed as a multilayer. The third semiconductor layer SEM3 may reduce in lattice constant between a second semiconductor material layer SEM2L and the second substrate 210. For example, the third semiconductor layer SEM3 may include an undoped semiconductor (e.g., a material not doped with an n- or p-type dopant). The third semiconductor layer SEM3 may include at least one of InAlGaN, GaN, AlGaN, InGaN, AlN, and InN that are not doped, but the present disclosure is not limited thereto.

The second semiconductor material layer SEM2L, a superlattice material layer SLTL, an active material layer MQWL, an electron-blocking material layer EBLL, and a first semiconductor material layer SEM1L are sequentially formed on the third semiconductor layer SEM3.

Thereafter, the light-emitting elements LE are formed by etching the second semiconductor material layer SEM2L, the superlattice material layer SLTL, the active material layer MQWL, the electron-blocking material layer EBLL, and the first semiconductor material layer SEM1L.

For example, first mask patterns MP1 and a second mask pattern MP2 are formed on the first semiconductor material layer SEM1L. The first mask patterns MP1 and the second mask pattern MP2 may be patterns of a hard mask including an inorganic material, or patterns of a photoresist mask including an organic material. The first mask patterns MP1 may be formed to be thicker than the second mask pattern MP2 to prevent parts of the second semiconductor material layer SEM2L, the superlattice material layer SLTL, the active material layer MQWL, the electron-blocking material layer EBLL, and the first semiconductor material layer SEM1L below the first mask patterns MP1 from being etched.

The second semiconductor material layer SEM2L, the superlattice material layer SLTL, the active material layer MQWL, the electron-blocking material layer EBLL, and the first semiconductor material layer SEM1L may be partially etched, as indicated by “1^{st} etch” in FIG. 30, by using the first mask patterns MP1 and the second mask pattern MP2 as a mask.

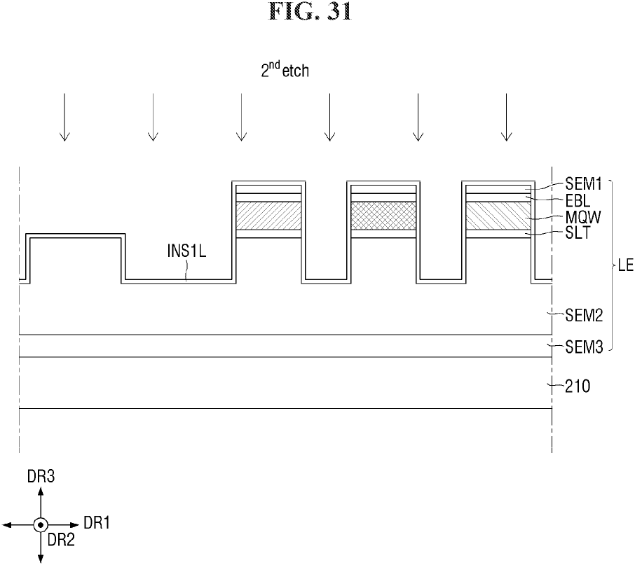

Referring to FIG. 31, parts of the second semiconductor material layer SEM2L, the superlattice material layer SLTL, the active material layer MQWL, the electron-blocking material layer EBLL, and the first semiconductor material layer SEM1L are etched away, and parts of the second semiconductor material layer SEM2L, the superlattice material layer SLTL, the active material layer MQWL, the electron-blocking material layer EBLL, and the first semiconductor material layer SEM1L that remain unetched on the second substrate 210 may be formed as the light-emitting elements LE. The second semiconductor material layer SEM2L, the superlattice material layer SLTL, the active material layer MQWL, the electron-blocking material layer EBLL, and the first semiconductor material layer SEM1L may be etched by a typical method. For example, the second semiconductor material layer SEM2L, the superlattice material layer SLTL, the active material layer MQWL, the electron-blocking material layer EBLL, and the first semiconductor material layer SEM1L may be etched by dry etching, wet etching, reactive ion etching (RIE), deep RIE (DRIE), or inductively-coupled plasma RIE (ICP-RIE). Dry etching allows anisotropic etching and is thus suitable for vertical etching. During the etching of the second semiconductor material layer SEM2L, the superlattice material layer SLTL, the active material layer MQWL, the electron-blocking material layer EBLL, and the first semiconductor material layer SEM1L, Cl₂, or O₂ may be used as an etchant, but the present disclosure is not limited thereto.

Parts of the second semiconductor material layer SEM2L, the superlattice material layer SLTL, the active material layer MQWL, the electron-blocking material layer EBLL, and the first semiconductor material layer SEM1L that overlap with the first mask patterns MP1 may not be etched away, and may be formed as the light-emitting elements LE. As the second mask pattern MP2 is etched away, parts of the superlattice material layer SLTL, the active material layer MQWL, the electron-blocking material layer EBLL, and the first semiconductor material layer SEM1L that overlap with the second mask pattern MP2 may also be etched away, and parts of the second semiconductor material layer SEM2L and the third semiconductor layer SEM3 that overlap with the second mask pattern MP2 may remain unetched. Parts of the superlattice material layer SLTL, the active material layer MQWL, the electron-blocking material layer EBLL, and the first semiconductor material layer SEM1L that do not overlap with the first mask patterns MP1 or the second mask pattern MP2 may be etched away, and parts of the second semiconductor material layer SEM2L and the third semiconductor layer SEM3 that do not overlap with the first mask patterns MP1 and the second mask pattern MP2 may not be etched away by controlling the etching of the semiconductor material layers (SEM3, SEM2L, SLTL, MQWL, EBLL, and SEM1L). A location in which to form the common connecting electrode 127 may be set by forming the second semiconductor material layer SEM2L to be relatively thick on an edge of the second substrate 210.

As a result, each of the light-emitting elements LE may be formed to include the third semiconductor layer SEM3, the second semiconductor layer SEM2, the superlattice layer SLT, the active layer MQW, the electron blocking layer EBL, and the first semiconductor layer SEM1. The third semiconductor layer SEM3 and the second semiconductor layer SEM2 may be formed to be located on the entire second substrate 210.

Thereafter, referring again to FIG. 29, the insulating layer INS1 is formed on the second substrate 210 including the light-emitting elements LE (S110).

For example, referring to FIG. 31, an insulating material layer INS1L is formed on the second substrate 210. The insulating material layer INS1L may completely cover the light-emitting elements LE. The insulating material layer INS1L may be formed by applying an insulating material on the second substrate 210 or immersing the second substrate 210 in an insulating material. For example, the insulating material layer INS1L may be formed by atomic layer deposition (ALD).

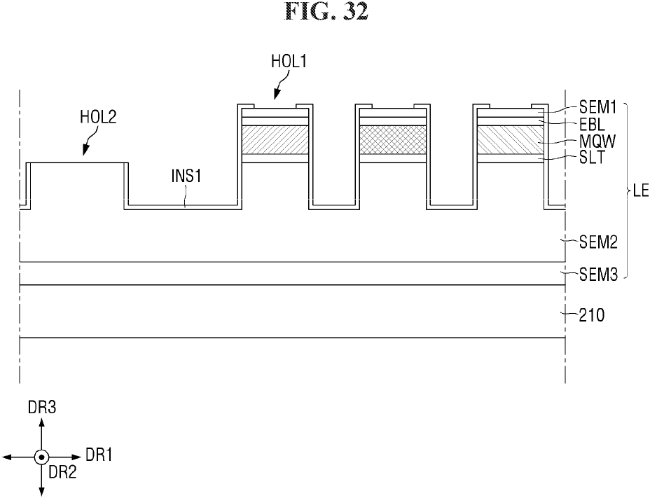

Thereafter, referring to FIG. 32, the insulating layer INS1, which includes or defines first contact holes HOL1 and a second contact hole HOL2 therein, is formed by partially etching the insulating material layer INS1L, as indicated by “2^{nd} etch” in FIG. 31, to expose the top surfaces of the light-emitting elements LE and parts of the second semiconductor layer SEM2 on the edge of the second substrate 210. The insulating material layer INS1L, or portions thereof, may be removed by one of the above-mentioned etching methods.

Thereafter, referring again to FIG. 29, the reflective layers RF1 are formed on the insulating layer INS1 (S120).

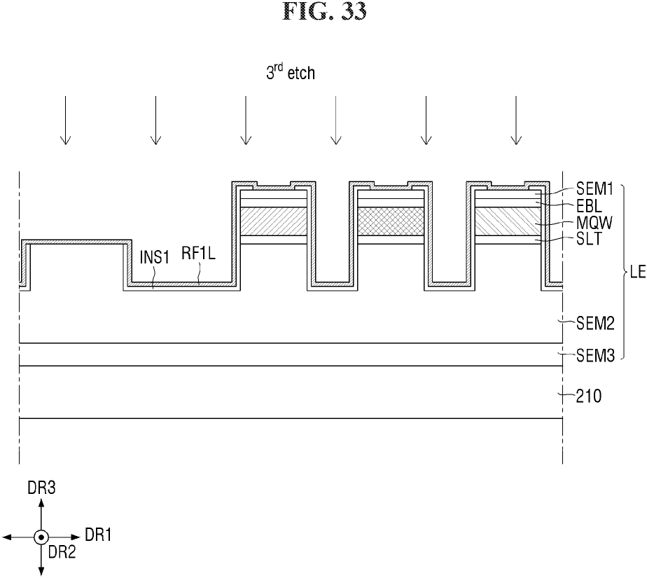

For example, referring to FIG. 33, a reflective material layer RF1L is formed on the second substrate 210 where the insulating layer INS1 is formed. The reflective material layer RF1L may include a metal with high reflectance, such as Al. The reflective material layer RF1L may be formed by a metal deposition method, such as sputtering. The reflective material layer RF1L may be stacked on the insulating layer INS1 and the light-emitting elements LE.

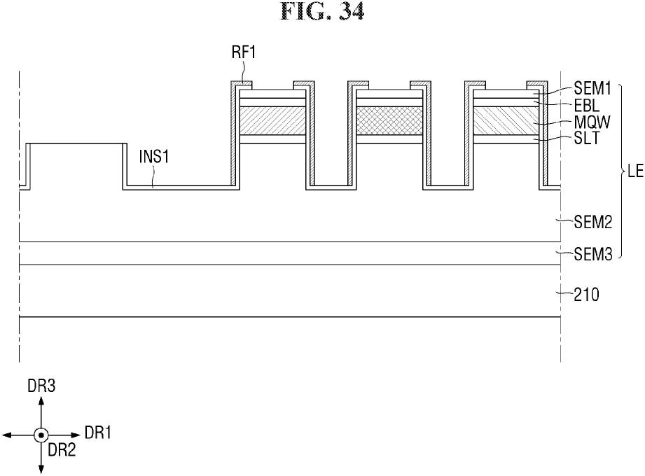

Thereafter, referring to FIGS. 33 and 34, the reflective layers RF1 are formed by etching the reflective material layer RF1L, as indicated by “3^{rd} etch” in FIG. 33. Parts of the reflective material layer RF1L that are stacked in parallel to the second substrate 210 may be removed by increasing the difference in voltage and using a corresponding etching gas (e.g., EG2) during the etching of the reflective material layer RF1L. On the contrary, parts of the reflective material layer RF1L on vertical sides of the second substrate 210 that are perpendicular to the top surface of the second substrate 210, for example, parts of the reflective material layer RF1L located on sides of each of the light-emitting elements LE, may not be removed.

Accordingly, the reflective layers RF1 may be located on parts of the insulating layer INS1 located on the sides of each of the light-emitting elements LE. That is, the reflective layers RF1 may be located on the vertical sides that are substantially perpendicular to the top surface of the second substrate 210.

Thereafter, referring again to FIG. 29, the light-emitting element layer 120 is formed (S130) by forming the connecting electrodes 126 on the light-emitting elements LE and forming the common connecting electrode 127, which includes the first conductive patterns COP1, on at least a portion of the second semiconductor layer SEM2 exposed on an edge of the second substrate 210.

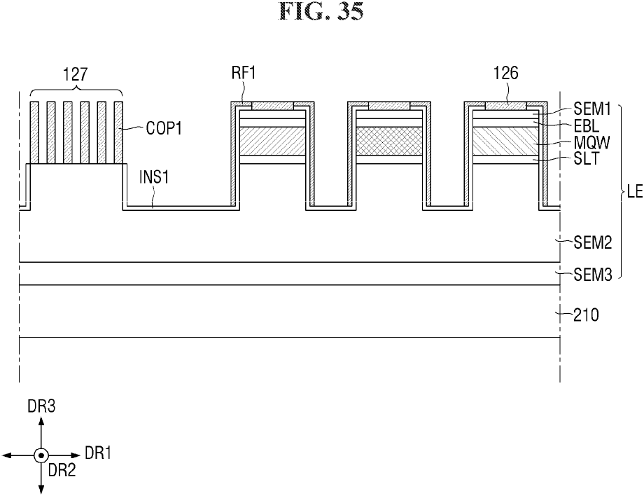

For example, referring to FIG. 35, the connecting electrodes 126 are formed on parts of the light-emitting elements LE exposed by the insulating layer INS1, by stacking a common electrode material layer on the second substrate 210, and by etching the common electrode material layer. The connecting electrodes 126 may be formed directly on the top surface of the first semiconductor layers SEM1 of the light-emitting elements LE. Then, the common connecting electrode 127 is formed on portion of the second semiconductor layer SEM2 exposed by the insulating layer INS1 on the edge of the second substrate 210. The common connecting electrode 127 may be formed directly on the top surface of the second semiconductor layer SEM2 to include the first conductive patterns COP1.

Thereafter, referring again to FIG. 29, the light-emitting element layer 120 is bonded onto the semiconductor circuit substrate 100 (S140).

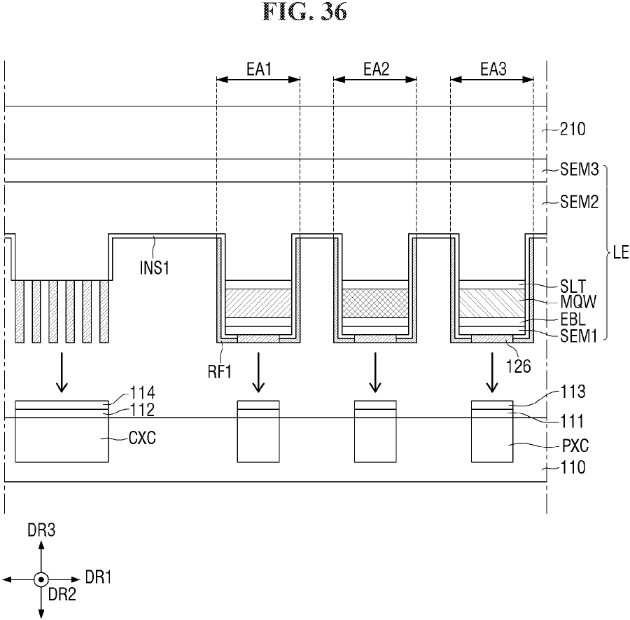

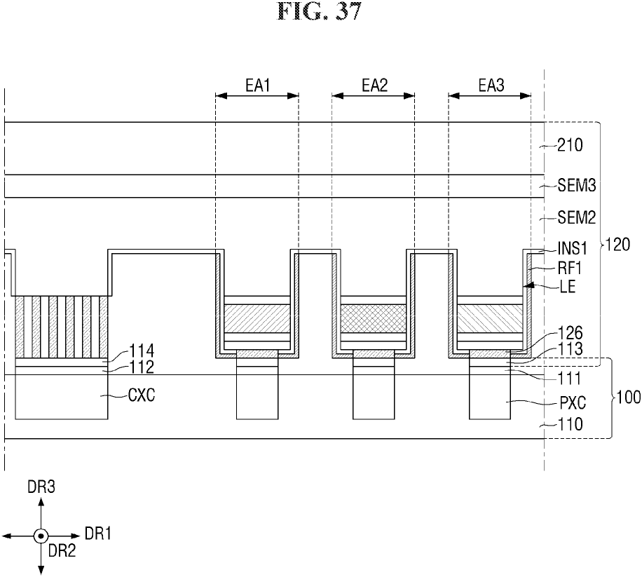

For example, referring to FIGS. 36 and 37, the semiconductor circuit substrate 100 is prepared. The semiconductor circuit substrate 100 may include, on the first substrate 110, the pixel circuit units PXC, the common circuit unit CXC, the pixel electrodes 111, the contact electrodes 113, the common electrode 112, and the common contact electrode 114.

The pixel electrodes 111 and the common electrode 112 are formed at the same time on the first substrate 110 where the pixel circuit units PXC and the common circuit unit CXC are formed. The contact electrodes 113 and the common contact electrode 114 are formed by stacking a contact electrode material layer on the pixel electrodes 111 and the common electrode 112 and etching the contact electrode material layer. The contact electrode material layer may include Au, Cu, Al, or Sn.

Thereafter, the light-emitting element layer 120 is aligned on the semiconductor circuit substrate 100, and the semiconductor circuit substrate 100 and the light-emitting element layer 120 are bonded together.

For example, the contact electrodes 113 of the semiconductor circuit substrate 100 are in contact with the connecting electrodes 126 of the light-emitting element layer 120. Also, the common contact electrode 114 of the semiconductor circuit substrate 100 is in contact with the common connecting electrode 127 of the light-emitting element layer 120. Thereafter, the semiconductor circuit substrate 100 and the light-emitting element layer 120 are bonded together by fusion-bonding the contact electrodes 113 and the common contact electrode 114 of the semiconductor circuit substrate 100 and the connecting electrodes 126 and the common connecting electrode 127 of the light-emitting element layer 120 while applying heat.

As described above with reference to FIGS. 29 through 37, as the common connecting electrode 127 of the light-emitting element layer 120 is formed to include the first conductive patterns COP1, the area of contact with the common contact electrode 114 of the semiconductor circuit substrate 100 can be reduced. As a result, the amounts of materials melted and flowing from the common connecting electrode 127 during the bonding of the semiconductor circuit substrate 100 and the light-emitting element layer 120 can be reduced so that short circuits with the light-emitting elements LE can be reduced or prevented.

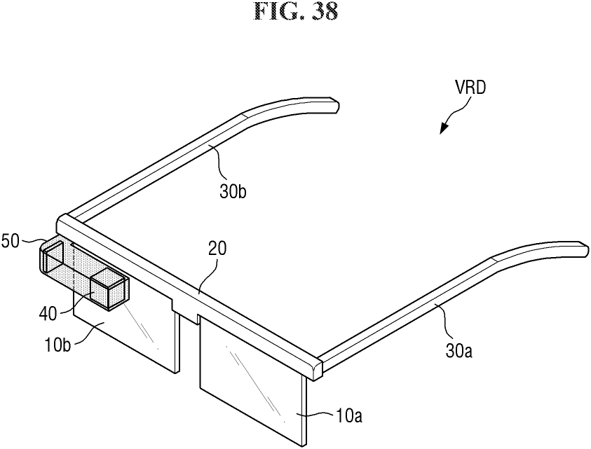

FIG. 38 is a perspective view of a virtual reality (VR) device including a display device, according to one or more embodiments of the present disclosure. FIG. 38 illustrates a VR device VRD, to which a display device 1 is applied.

Referring to FIG. 38, the VR device VRD may be an eyeglass-type device. The VR device VRD may include the display device, a left-eye lens 10a, a right-eye lens 10b, a support frame 20, eyeglass temples 30a and 30b, a reflective member 40, and a display device storage compartment 50.

FIG. 38 illustrates the VR device VRD including the eyeglass temples 30a and 30b, but the VR device VRD may also be applicable to a head-mounted display (HMD) including a headband that can be worn on the head, instead of the eyeglass temples 30a and 30b. That is, the VR device VRD is not particularly limited to that illustrated in FIG. 38 and may be applicable to various types of electronic devices.

The display device storage compartment 50 may include the display device 1 and the reflective member 40. An image displayed by the display device 1 may be reflected by the reflective member 40 and may thus be provided to the right eye of a user through the right-eye lens 10b. Thus, the user may view a VR image, displayed by the display device 1, through his or her right eye.

FIG. 38 illustrates that the display device storage compartment 50 is located at the right end of the support frame 20, but the present disclosure is not limited thereto. Alternatively, the display device storage compartment 50 may be located at the left end of the support frame 20, in which case, an image displayed by the display device 1 may be reflected by the reflective member 40, and may thus be provided to the right eye of the user through the left-eye lens 10a. Accordingly, the user can view a VR image displayed by the display device 1 with his or her left eye. Yet alternatively, two display device storage compartments 50 may be respectively located at the left and right ends of the support frame 20, in which case, the user can view the VR image displayed by the display device 1 with both his or her left and right eyes.

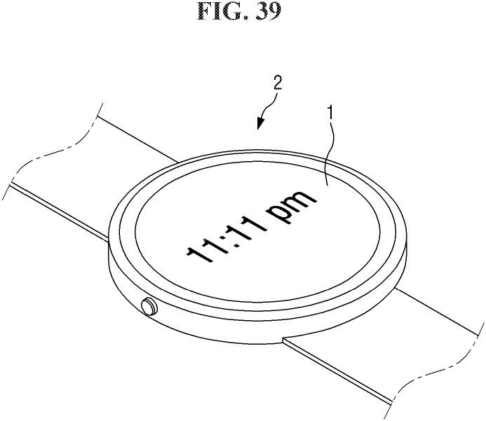

FIG. 39 is a perspective view of a smart device including a display device, according to one or more embodiments of the present disclosure.

Referring to FIG. 39, a display device 1 may be applied to a smartwatch 2, which is a type of smart device.

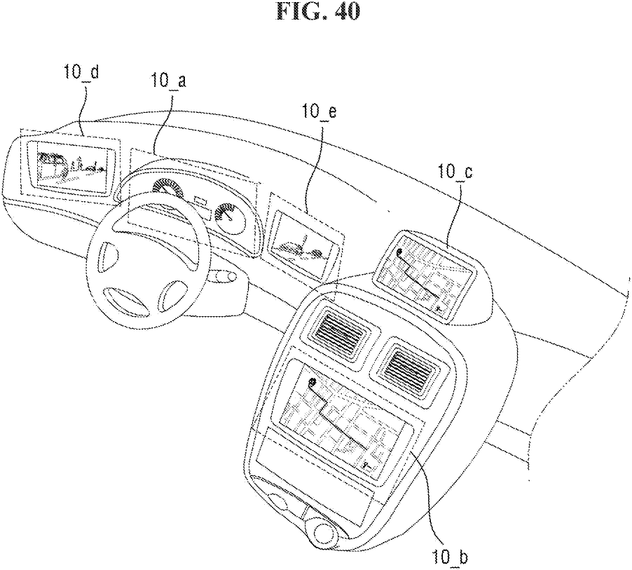

FIG. 40 is a perspective view of an automobile including a display device, according to one or more embodiments of the present disclosure. FIG. 40 illustrates an automobile, to which display panels 10_a, 10_b, 10_c, 10_d, and 10_e are applied.

Referring to FIG. 40, the display panels 10_a, 10_b, and 10_c may be applied to the dashboard or center console of an automobile or to a center information display (CID) in the dashboard of an automobile. The display panels 10_d and 10_e may be applied to room mirror displays that can replace the rear view mirrors of an automobile.

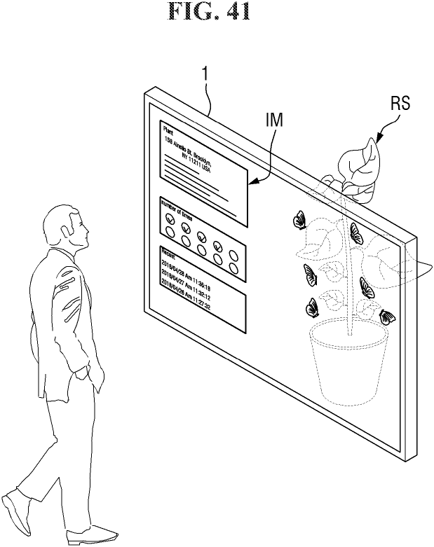

FIG. 41 is a perspective view of a transparent display device including a display device, according to one or more embodiments of the present disclosure.

Referring to FIG. 41, a display device 1 may be applied to a transparent display device. The transparent display device may display an image lM and at the same time, transmit light therethrough. Thus, a user at the front of the transparent display device may view not only the image lM on the display device 1, but also an object RS or the background at the rear of (e.g., behind) the transparent display device. In a case where the display device 1 is applied to the transparent display device, a semiconductor circuit substrate (e.g., see semiconductor circuit substrate 100 of FIG. 4) of the display device 1 may include light-transmitting parts capable of transmitting light therethrough or may be formed of a material capable of transmitting light therethrough.

In concluding the detailed description, those skilled in the art will appreciate that many variations and modifications can be made to the embodiments without substantially departing from the aspects of the present disclosure. Therefore, the disclosed embodiments are used in a generic and descriptive sense only and not for purposes of limitation.

What is claimed is:

1. A display device comprising:
a substrate;
contact electrodes and a common contact electrode on the substrate;
light-emitting elements respectively on the contact electrodes; and
a common connecting electrode on the common contact electrode, connected to the light-emitting elements, and comprising first conductive patterns in contact with the common contact electrode.

2. The display device of claim 1, wherein the first conductive patterns are spaced apart from one another, and are formed as dots or lines.

3. The display device of claim 1, wherein the light-emitting elements comprise a first semiconductor layer, an active layer on the first semiconductor layer, a second semiconductor layer on the active layer, and a third semiconductor layer on the second semiconductor layer, and
wherein the second semiconductor layer is a common layer connected in common to the light-emitting elements.

4. The display device of claim 3, wherein the first conductive patterns are between, and in contact with, the second semiconductor layer and the common contact electrode.

5. The display device of claim 1, wherein the first conductive patterns comprise a same material as the contact electrodes.

6. The display device of claim 1, wherein the first conductive patterns account for about 10% to about 50% of a total area of the common contact electrode.

7. The display device of claim 1, wherein the common contact electrode further comprises second conductive patterns spaced apart from one another, and respectively overlapping the first conductive patterns.

8. The display device of claim 7, wherein the second conductive patterns correspond one-to-one to the first conductive patterns.

9. The display device of claim 7, further comprising a common electrode between the substrate and the common contact electrode,
wherein the second conductive patterns account for about 10% to about 50% of a total area of the common electrode.

10. The display device of claim 1, wherein the light-emitting elements are in a display area, and
wherein the common contact electrode and the common connecting electrode are in a non-display area surrounding the display area.

11. A display device comprising:
a substrate;
contact electrodes and a common contact electrode on the substrate;
light-emitting elements on the contact electrodes; and
a common connecting electrode on the common contact electrode, and connected to the light-emitting elements,
wherein the common contact electrode comprises conductive patterns, which are in contact with the common connecting electrode.

12. The display device of claim 11, wherein the conductive patterns account for 10% to 50% of a total area of the common connecting electrode.

13. A display device comprising:
a substrate comprising a display area and a non-display area;
light-emitting elements in the display area; and
dummy patterns in the non-display area, adjacent to at least one side of the substrate, and having respective lengths that gradually increase away from a center of a first side of the substrate.

14. The display device of claim 13, wherein the first side of the substrate is a long side of the substrate, and
wherein the lengths of the dummy patterns extend along the long side.

15. The display device of claim 14, wherein the dummy patterns are further located along a second side extending in a direction crossing a direction of the first side of the substrate, the second side being a short side of the substrate.

16. The display device of claim 13, wherein the light-emitting elements comprise a first semiconductor layer, an active layer on the first semiconductor layer, a second semiconductor layer on the active layer, and a third semiconductor layer on the second semiconductor layer, and
wherein the display device further comprises connecting electrodes connected to the first semiconductor layer.

17. The display device of claim 16, wherein the dummy patterns comprise a same material as the connecting electrodes.

18. A display device comprising:
a substrate comprising a display area and a non-display area; and
light-emitting elements in the display area,
wherein the substrate defines holes in the non-display area, adjacent to at least one side of the substrate, and having respective lengths gradually increasing away from a center of the at least one side of the substrate.

19. The display device of claim 18, wherein the holes penetrate the substrate.

20. The display device of claim 18, wherein the holes are formed in the substrate.
